(19) United States
(12) Patent Application Publication
(10) Pub. No.: US 2025/0351499 A1
(43) Pub. Date: Nov. 13, 2025

(54) HETEROJUNCTION SEMICONDUCTOR POWER DEVICES USING DIFFERENT BANDGAP SEMICONDUCTORS

(71) Applicant: MaxPower Semiconductor, Inc., San Jose, CA (US)

(72) Inventors: Mohamed Darwish, San Jose, CA (US); Jun Zeng, San Jose, CA (US); Danilo Crippa, Novara (IT)

(73) Assignee: MaxPower Semiconductor, Inc., San Jose, CA (US)

(21) Appl. No.: 19/241,246

(22) Filed: Jun. 17, 2025

Related U.S. Application Data
(63) Continuation-in-part of application No. 18/658,910, filed on May 8, 2024.
(60) Provisional application No. 63/733,623, filed on Dec. 13, 2024.
(60) Provisional application No. 63/742,724, filed on Jan. 7, 2025.

(51) Int. Cl. H10D 62/822; H01L 21/18; H01L 21/762; H10D 8/00; H10D 8/60; H10D 30/01; H10D 30/66; H10D 62/10; H10D 62/60; H10D 62/82; H10D 84/00; H10D 84/01; H10D 86/00; H10D 86/01

(52) U.S. Cl. CPC H10D 62/822; H01L 21/187; H01L 21/76251; H01L 21/76256; H10D 8/422; H10D 8/60; H10D 30/0297; H10D 30/668; H10D 62/107; H10D 62/60; H10D 62/82; H10D 84/0107; H10D 84/143; H10D 84/146; H10D 86/01; H10D 86/201

(57) ABSTRACT

Trench-gate MOSFETs use a N+ SiC substrate with a N SiC drift layer. A Si wafer is bonded to the top of the SiC wafer, forming a Si/SiC heterojunction at the interface. Gate trenches are formed in the Si layer, oxidized, and filled with a conductor. Since the gate oxide is only in contact with the Si, and not the SiC, there is no problem with carbon at the gate oxide interface. Also, since the MOSFET is formed in the Si layer, electron mobility near the gates is high. JFET channel regions in the SiC layer pinch off during short circuit, high current conditions to limit drain current and thus achieve a higher short circuit withstand time capability. At the Si/SiC interface, a thin, highly doped n-type layer is formed in the SiC layer that allows tunneling current flowing through the barrier to lower the voltage drop across the heterojunction.

### CROSS-REFERENCE TO RELATED APPLICATIONS

This application is a continuation-in-part of U.S. application Ser. No. 18/658,910, filed May 8, 2024, now publication US 2024/0379838, published Nov. 24, 2024, by Mohamed Darwish et al.

This application also claims priority from U.S. provisional application Ser. No. 63/733,623, filed Dec. 13, 2024, and provisional application Ser. No. 63/742,724, filed Jan. 7, 2025, both by Mohamed Darwish et al. and incorporated herein by reference.

### FIELD OF THE INVENTION

This invention relates to vertical power MOSFETs and, in particular, to such power MOSFETs using wide bandgap layers, such silicon carbide (SiC), and narrower bandgap layers, such as silicon (Si).

### BACKGROUND

Power MOSFETs are widely used as switching devices in many electronic applications. It is desirable that power MOSFETs have both low power losses and high reliability. MOSFETs formed of SiC, rather than Si, have improved temperature stability, higher breakdown voltage (allowing for a thinner drift region and higher doping concentration), faster switching, and a smaller size. The thinner drift region and higher doping concentration enable MOSFETs formed of SiC to have a lower voltage drop when the MOSFET is turned on.

The existence of carbon at the gate oxide interface in SiC MOSFETs results in lower channel mobility, which increases the channel resistance, and adversely affects the gate oxide stability and reliability. The low channel mobility necessitates the use of a higher gate-to-source voltage to drive the MOSFET in the on-state. For example, to fully turn on a SiC MOSFET, a gate voltage of typically 15V-20V is needed versus 5V-10V in the case of silicon power MOSFETs. Furthermore, a negative gate bias may be needed to turn off the SiC MOSFET, which requires modification of existing drivers designed for silicon MOSFETs.

Further, if Si layers and SiC layers are bonded together at an Si/SiC interface, there are significant voltage drop losses at the interface due to the differences between the Si and SiC materials. Si has a bandgap that is narrower than that of SiC. As a result, at the interface there is rectification, where the Si layer is reverse biased with respect to the SiC layer when an n-type MOSFET is switched on. It is desirable to reduce such losses at the interface.

What is needed is a vertical power MOSFET that has the benefits of the SiC and Si layers without the drawbacks described above.

### SUMMARY

New trench-gate MOSFET structures and their methods of fabrication are disclosed. The MOSFETs are cellular, with an array of identical cells being connected in parallel.

An N+ SiC substrate has epitaxially grown over it an N SiC drift layer having the thickness and doping concentration needed to support a particular voltage. A Si wafer is then bonded to the top of the SiC wafer, forming a Si/SiC heterojunction at the interface. Gate trenches are formed in the Si layer. Si has a narrow bandgap while SiC has a wide bandgap.

The Si layer has a much thinner N drift region, a P-body (or P-well) formed in the Si layer overlying the Si drift region, and N+ source regions formed in or on the P-body. Gate trenches are then etched through the P-body and terminate in the Si drift region. The trenches are oxidized to form a gate oxide, and the trenches are filled with a gate conductor, such as doped polysilicon.

Therefore, since the gate oxide is only in contact with the Si, and not the SiC, there is no problem with carbon at the gate oxide interface. Also, since the MOS gate is formed in the Si layer, electron mobility near the gates is high. All the advantages of SiC are utilized in the SiC drift region and highly conductive N+ SiC substrate layer.

In a preferred embodiment, P-type regions are formed in the SiC drift layer generally between each of the trench gates. The junctions of the P-type regions and N-type SiC drift region support a high breakdown voltage when the MOSFET is turned off. These P-type regions form gates of JFETs, with the N-type SiC between the P-type regions forming channel regions. Furthermore, the JFET N-type channel regions (generally below the trenches) pinch off during short circuit, high current conditions to limit drain current and thus achieve a higher short circuit withstand time capability. In addition, at reverse bias, the JFET gate regions shield the gate trench bottom and protect the gate oxide by reducing the electric field.

At the Si/SiC interface, a highly doped N-type layer is formed in the SiC layer, with a doping concentration that is higher than the JFET channel regions. The N-type layer is formed to be very thin (less than 0.5 micron). This highly doped top N-type layer creates a Si/SiC heterojunction conduction band barrier that is sufficiently thin to achieve a significant enhancement of the tunneling current flowing through the barrier. The tunnelling occurs at the interface of the highly doped SiC N-type layer and the Si. The high tunneling current lowers the voltage drop across the heterojunction in the MOSFET's on-state, resulting in a great improvement in device performance. Without the highly doped N-type layer, rectification would occur at the interface when the MOSFET is on. The tunnelling current may include thermonic emissions.

The SiC layers may instead be replaced by another wide bandgap layer such as formed of GaN.

Other embodiments are described.

### BRIEF DESCRIPTION OF THE DRAWINGS

FIG. 1(a) illustrates a MOSFET cell, in accordance with one embodiment of the invention, with one or more trench gates formed within silicon (Si) and having a drift region formed of SiC, where the interface between the two materials forms a bonded Si/SiC heterojunction, with a highly doped and thin N-type layer (N3) at the top of the SiC layer. JFETs are formed in the SiC layer below the N-type layer.

FIG. 1(b) shows a MOSFET structure similar to that shown in FIG. 1(a) but with the thin, highly doped N-type layer (at the Si/SiC heterojunction interface) being even with and below the top of the P-type JFET gate regions.

FIG. 1(c) shows a MOSFET structure similar to that shown in FIG. 1(b) but with the N-type layer (at the Si/SiC heterojunction interface) being formed of discrete areas that do not adjoin the P-type JFET gate regions.

FIG. 1(d) shows a MOSFET structure similar to that shown in FIG. 1(a) but uses embedded trench gate electrodes, where a dielectric material over the gate conductor is flush with the bottom of the source metal.

FIG. 1(e) shows a MOSFET structure similar to that shown in FIG. 1(a) but uses planar gates instead of trenched gates.

FIG. 2 shows a MOSFET structure similar to that shown in FIG. 1(a) but with JFET channels offset from the bottoms of the gate trenches.

FIG. 3(a) shows a MOSFET structure similar to that shown in FIG. 1(a) but with an additional Si n-type (n3) layer at the Si/SiC interface abutting the high doped and thin N-type layer in the SiC layer.

FIG. 3(b) shows a MOSFET structure similar to that shown in FIG. 3(a) but with SiC N-type (N3) regions that do not adjoin the P-type JFET gates.

FIG. 3(c) shows a MOSFET structure similar to that shown in FIG. 3(b) but with the top of the JFET gate regions being at the Si/SiC heterojunction interface.

FIG. 4(a) shows a MOSFET structure similar to that shown in FIG. 1(a) but with a thick bottom-oxide gate trench.

FIG. 4(b) shows a MOSFET structure similar to that shown in FIG. 1(a) but with a split gate structure.

FIG. 4(c) shows a MOSFET structure similar to that shown in FIG. 1(c) but with a split gate structure.

FIG. 5(a) illustrates an area of a MOSFET cell showing how the JFET gate regions are shorted to the source metal by a P+ contact region (Pc) extending between the source metal and the top of the JFET gate regions. All JFET gate regions are connected together outside the plane of the figure.

FIG. 5(b) shows a MOSFET structure similar to that shown in FIG. 5(a) but where the N-type (N3) region in the SiC layer does not adjoin the JFET P-type gate regions.

FIG. 5(c) shows a MOSFET structure similar to that shown in FIG. 5(b) but with P+ contact regions at the top of the P-type JFET gate regions in the SiC layer to improve the contact between the Pc and Pg regions of the JFETs.

FIG. 6(a) shows a MOSFET structure similar to that shown in FIG. 5(a) but shows how any number of trench gates can be surrounded by the P+ contact region for the JFET gate regions.

FIG. 6(b) shows a MOSFET structure similar to that shown in FIG. 6(a) but where the N-type (N3) regions in the SiC layer do not adjoin the JFET P-type gate regions.

FIG. 6(c) shows a MOSFET structure with a number of gate trenches surrounded by a P+ contact region (Pc) for the JFET gate regions with an additional Si n-type (n3) layer. The doping concentration of n3 is higher than the drift region n4.

FIG. 7(a) illustrates how the JFET gate regions can be connected to the source metal by a conducting material in a second trench that is surrounded by a dielectric layer such silicon dioxide (oxide), and the second trench extending below the Si/SiC interface.

FIG. 7(b) shows a MOSFET structure similar to that shown in FIG. 7(a) but where the N-type (N3) regions do not adjoin the JFET gate regions (Pg).

FIG. 7(c) shows a MOSFET structure similar to that shown in FIG. 7(a) but with the top of the JFET P-type gate regions being below the Si/SiC heterojunction interface.

FIG. 7(d) shows a MOSFET structure similar to that shown in FIG. 7(c) but with an additional n-type n3 silicon layer.

FIG. 7(e) shows a MOSFET structure similar to that shown in FIG. 7(c) but where the N-type (N3) regions do not adjoin the JFET P-type gate regions.

FIG. 8(a) illustrates how the vertical MOSFET can be only a portion of a die, where any other integrated circuit (IC) components can be formed in the Si.

FIG. 8(b) shows a device similar to that shown in FIG. 8(a) but where the N-type (N3) regions do not adjoin the JFET P-type gate regions.

FIG. 8(c) shows a device similar to that shown in FIG. 8(a) but shows a P-buried layer (Pbl) for electrically isolating the n-type Si drift layer in the MOSFET and the SiC layers from the n-type Si layer portion used for other integrated circuit (IC) components.

FIG. 8(d) shows a device similar to that shown in FIG. 8(a) but with the JFET gate regions connected to the source metal by a conducting material in a second trench that is surrounded by a dielectric layer such silicon dioxide (oxide), and the top of the JFET gate regions is below the Si/SiC heterojunction interface.

FIG. 8(e) shows a device similar to that shown in FIG. 8(d) but where the N-type (N3) regions do not adjoin the JFET P-type gate regions.

FIG. 8(f) shows a device similar to that shown in FIG. 8(d) but with a P-buried layer (Pbl).

FIG. 9(a) shows a heterojunction diode formed by the Si drift region (n4) and the SiC region (N5) in parallel with the vertical MOSFET.

FIG. 9(b) shows a device similar to that shown in FIG. 9(a) but where the heterojunction diode is surrounded by a P+ contact region (Pc) extending between the source metal and the top of the JFET gate regions. The P+ contact region is formed around trenches that are not gate trenches.

FIG. 10(a) shows a Schottky diode formed in parallel with a vertical MOSFET.

FIG. 10(b) illustrates the formation of a PN diode between two gate trenches.

FIG. 11(a) illustrates a top-down view of strips of cells (containing gate trenches) surrounded by deep P+ regions (Pc contact regions of FIG. 6(a)), for shorting the P-type JFET gate regions to the source metal, and showing locations of the JFET gate regions Pg) between the strips of gate trenches.

FIG. 11(b) is similar to that shown in FIG. 11(a) but using the second trench of FIG. 7(a) to connect the JFET gate regions to the source metal.

FIG. 11(c) illustrates a top-down view of rectangular cells (containing gate trenches) surrounded by the deep P+ contact region of FIG. 6(a), for shorting the JFET gate regions to the source metal, and showing locations of the JFET gate regions between the rectangular gate trenches.

FIGS. 12(a)-12(h) illustrate process steps for forming the MOSFET embodiment of FIG. 7(d) which are easily adaptable to forming any of the other embodiments.

FIG. 13(a) and FIG. 13(b) show alternative steps of forming a device with an N-type layer (N3) in the SiC layer that does not adjoin the JFET gate regions.

FIG. 14(a) and FIG. 14(b) show an alternative method of direct bonding of Si and SiC wafers, using a Si wafer with a Si epitaxial drift layer (n4) and a Si n+ substrate followed by grinding and chemical mechanical polishing (CMP) the Si substrate to the desired thickness.

FIGS. 15(a)-(c) show an alternative method of direct bonding using a Silicon-on-Insulator (SOI) wafer with the desired epi thickness and doping.

FIGS. 16(a)-(d) show a method of forming the P-type JFET gate regions using trenches, where the P-type JFET gate regions are grown in the SiC trenches, followed by growing a SiC seed layer over the surface and bonding a Si wafer to the seed layer.

Elements that are the same or equivalent are identified with the same numeral.

### DETAILED DESCRIPTION OF EMBODIMENTS

In the examples below, the MOSFETs are cellular, with an array of identical cells being connected in parallel. Therefore, only a single cell needs to be described in detail.

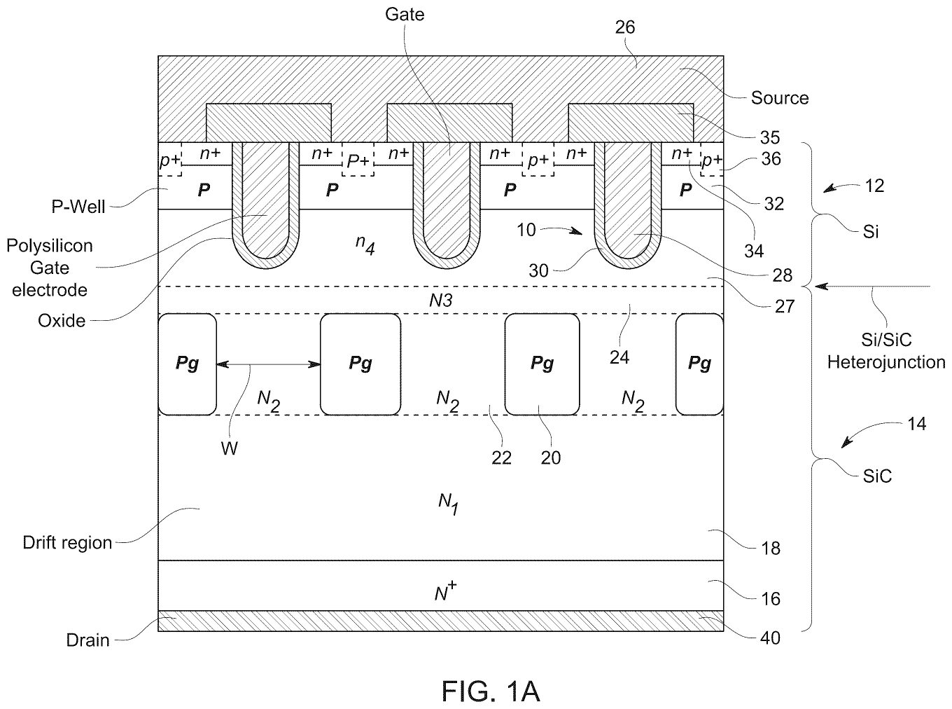

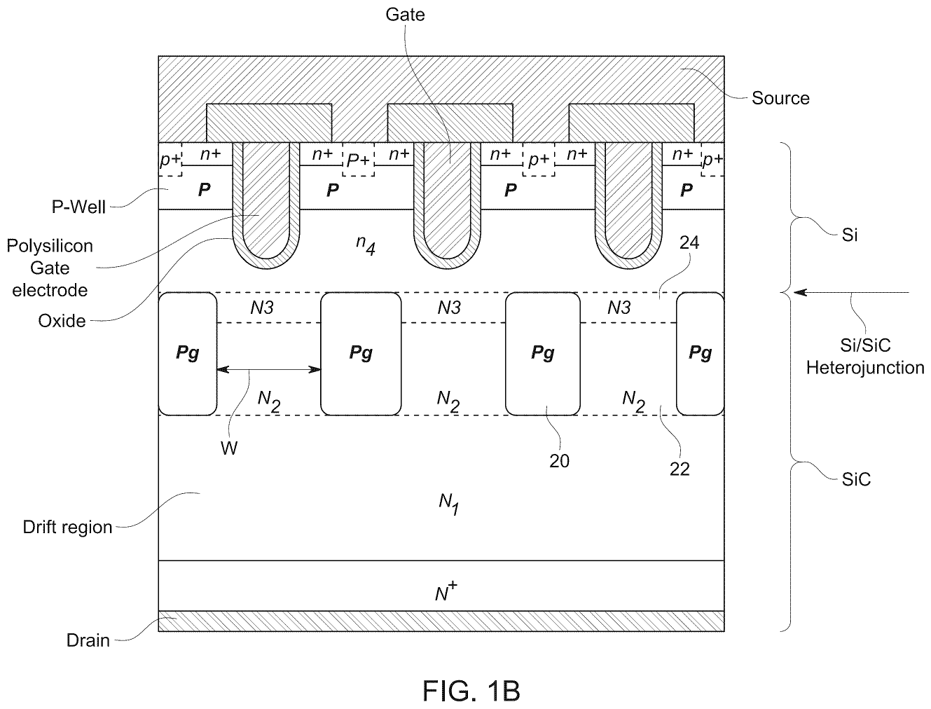

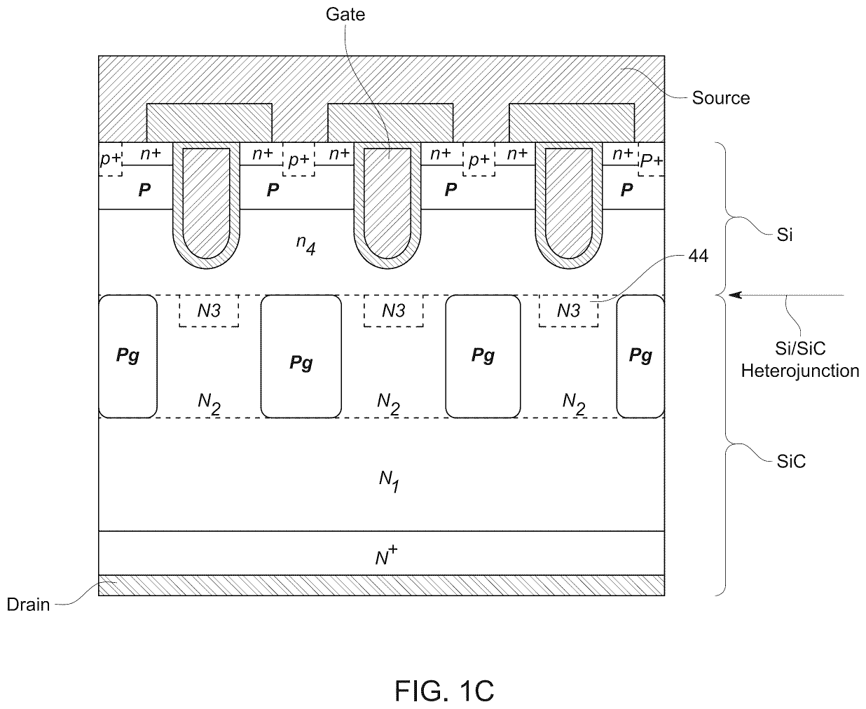

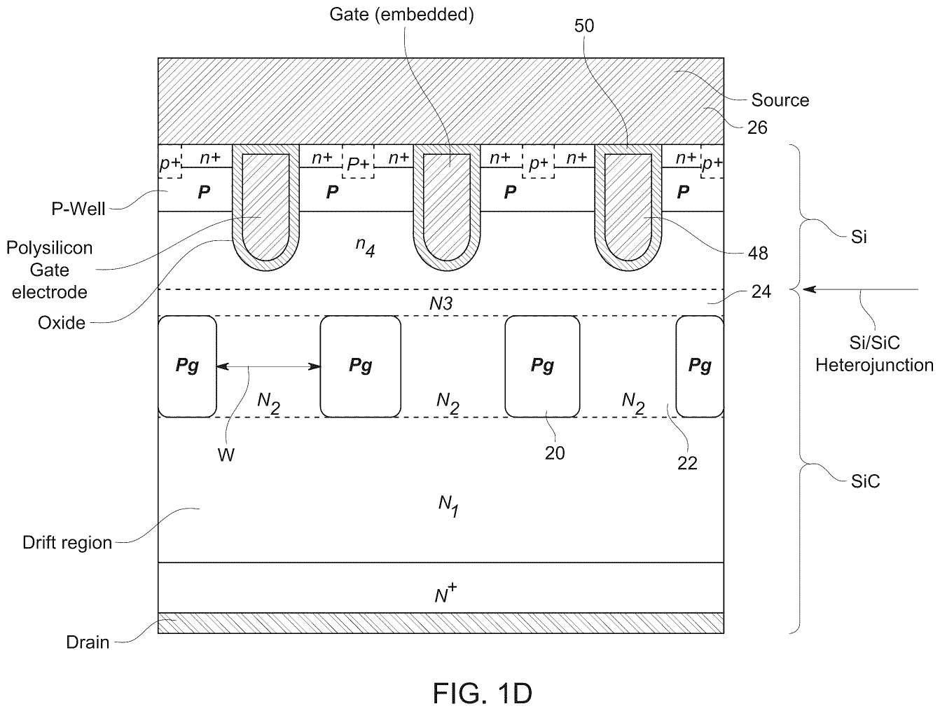

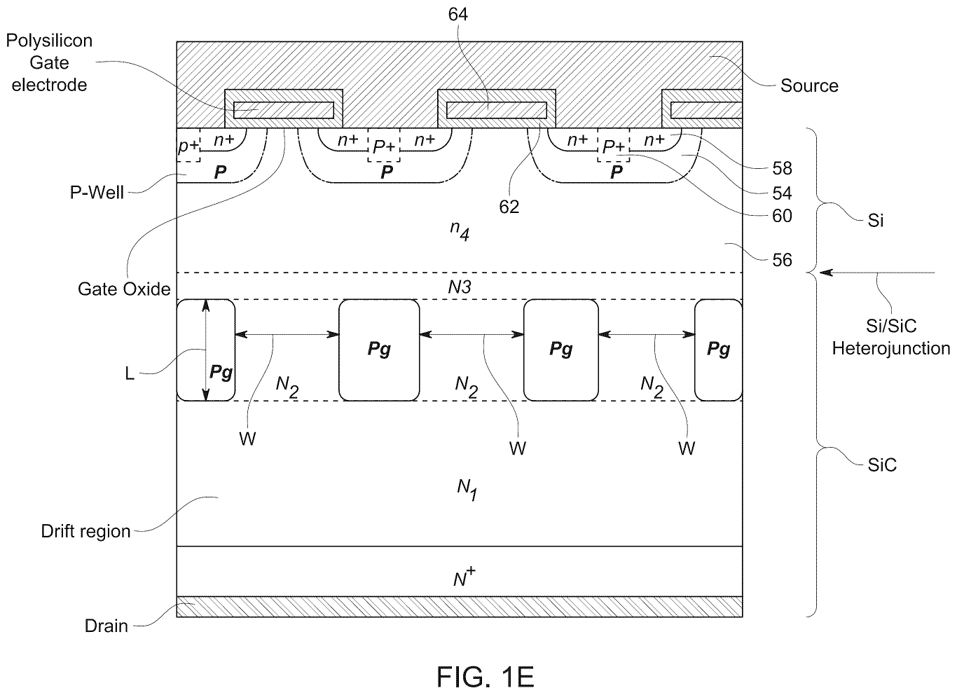

FIG. 1(a) illustrates one embodiment of the invention. A MOSFET cell has one or more trench gates 10 in a narrow bandgap semiconductor layer, such as a top silicon (Si) layer 12, where the Si layer 12 is over a wider bandgap semiconductor, such as a silicon carbide (SiC) layer 14, forming a Si/SiC heterojunction. The structure can be fabricated using direct wafer bonding of the Si and SiC layers, preferably at room temperature. The trench gates 10 are completely within the Si layer 12, providing a higher gate oxide reliability.

A bottom N+ substrate 16 can be formed of monocrystalline SiC or a polycrystalline SiC (PolySiC) material. A much lower dopant concentration N1 drift region 18 of SiC is epitaxially grown over the substrate 16 for supporting a depletion layer when the device is off.

In an alternative embodiment (not shown), a thinner n-type buffer layer, of a higher doping concentration than that of the drift region 18 and less than the substrate 16, can also be used between the drift region 18 and the substrate 16.

The SiC layer 14 includes a top portion that forms a JFET, which includes P-type JFET gate regions (Pg) 20 separated by N-type JFET channel regions 22 of doping N2. The channel regions 22 have a width W. The N2 doping concentration of the channel region 22 can be the same as, but preferably higher, than that of the N1 doping concentration of the drift region 18. The charge in the JFET gate regions 20 and the channel regions 22 can be adjusted to form a charge balanced superjunction (about 2×10¹³ cm⁻² in SiC) to maximize the breakdown voltage and lower the specific on-resistance.

The SiC layer 14 also includes a thin top n-type layer 24 of about 0.5 micron or less, with a doping concentration N3 that is higher than the JFET channel regions 22. The highly doped top n-type layer 24, with a surface dopant concentration greater than, for example, 1×10¹⁸ cm⁻³, creates a Si/SiC heterojunction conduction band barrier that is sufficiently thin to cause a significant enhancement of the tunneling current that flows through the barrier. The tunnelling occurs at the interface of the highly doped SiC N-type layer and the Si. The high tunneling current lowers the voltage drop across the heterojunction in the MOSFET's on-state. Without the n-type layer 24, rectification would occur at the interface of the narrow bandwidth and wider bandwidth materials.

The P-type JFET gate regions 20 are connected to a source metal 26 (source electrode) at certain locations (outside the view of FIG. 1(a)) via a p+ contact region (described later). There may be a connection to the source metal 26 at distributed locations in the cell array. Alternatively, the JFET gate regions 20 are not connected to the source metal 26 and are floating as islands of p-type SiC regions.

The Si top layer 12 is doped with an n-type dopant of dopant concentration n4 to form a second drift region 27 and includes one or more trench gate electrodes 28 of a conductive material, such as doped polysilicon. The gate electrodes 28 are surrounded by a dielectric material, such as silicon dioxide (forming a gate oxide 30).

A p-type body region 32 (or well region) is implanted in the Si top layer 12. N+ source regions 34 are implanted in the body region 32, and p+ body contact regions 36 are also implanted. The source regions 34 and body contact regions 36 are connected to the source metal 26. A dielectric 35 insulates the gate electrodes 28 from the source metal 26.

The trench gates 10, the n+ source regions 34, the body region 32, the p+ contact regions 36, and the second drift region 27 are all formed in the Si layer 12. As previously mentioned, the Si layer 12 may form a wafer that is bonded to the top surface of the SiC wafer. The various regions in the Si layer 12 may be formed before or after the bonding.

A bottom drain metal 40 is formed on the bottom surface of the substrate 16.

Under the MOSFET's reverse bias conditions, the voltage drops substantially across the SiC JFET channel regions 22 and the SiC drift region 18 and only a small voltage drop occurs across the top Si MOSFET portion, primarily due to the Si layer 12 being much thinner than the SiC layer 14. Also, only a small portion of the total voltage drop occurs across the n-N heterojunction formed at the Si/SiC layers interface due to the tunnelling n-type layer 24. This allows forming a high density of trench gates 10 with short MOSFET channel length (<0.25 um), which results in a lower specific on-resistance. Furthermore, the JFET N-type channel regions 22 pinch off during short circuit high current conditions to limit drain current and thus achieve a higher short circuit withstand time capability. In addition, at reverse bias, the JFET gate regions 20 shield the gate trench bottom and protect the gate oxide 30 by reducing the electric field.

To turn the device on, a positive bias is applied to the gate trench electrodes 28 (via a top gate pad), which inverts the P-body region 32 adjacent to the trench gates 10 to form electron inversion and accumulation layers (a conductive channel) around the trench gates 10. The electron current flows generally vertically from the source metal 26, through the n+ source regions 34, the inverted channel, the n-drift region 27, the Si/SiC heterojunction, the JFET channel regions 22, the drift region 18, the SiC substrate 16, and the drain metal 40.

Other semiconductor materials may be used as long as the top layer has a bandgap that is narrower than the bottom layer and the heterojunction is of the same dopant type n-N.

This structure provides the advantages of higher breakdown voltage, lower specific on-resistance, higher thermal conductivity of the SiC material, higher reliability carbon-free gate oxide, and ease of gate drive of the silicon material.

FIG. 1(b) shows a MOSFET structure similar to that shown in FIG. 1(a) but with the SiC n-type layer 24 being formed in the channel region 22 between the JFET gate regions 20. The top of the JFET gate regions 20 is at the Si/SiC heterojunction interface.

FIG. 1(c) shows a MOSFET structure similar to that shown in FIG. 1(b) but with the highly doped n-type layer 44 (at the Si/SiC heterojunction interface) being formed of discrete areas that do not adjoin the P-type JFET gate regions 20.

FIG. 1(d) shows a MOSFET structure that similar to that shown in FIG. 1(a) but uses embedded trench gate electrodes 48 with an oxide layer 50 formed over the doped polysilicon to insulate the gate electrodes 48 from the source metal 26.

FIG. 1(e) shows a MOSFET structure similar to that shown in FIG. 1(a) but uses planar gates instead of trenched gates. P-type body regions 54 are implanted in the Si layer 56, followed by implanting n+ source regions 58 and p+ body contacts 60. A gate oxide 62 insulates the polysilicon gate 64 from the channel region at the top of the body regions 54. When the gate 64 is biased above a threshold voltage, a conductive channel is formed in the body regions 54 to conduct a vertical current.

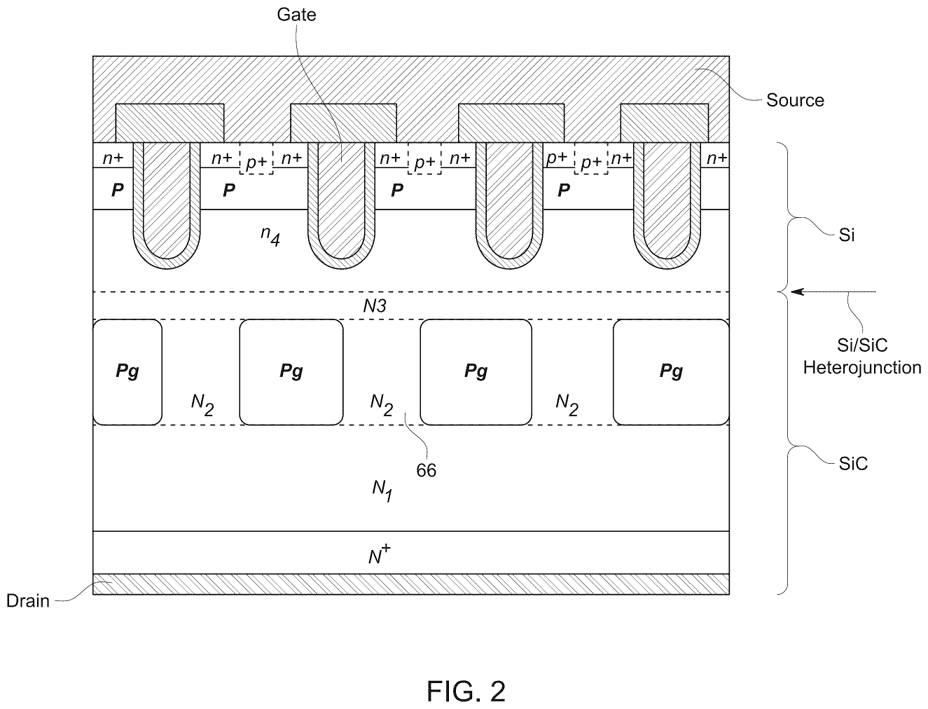

FIG. 2 shows a MOSFET structure similar to that shown in FIG. 1(a) but with the JFET channel regions 66 being offset from the gates 10.

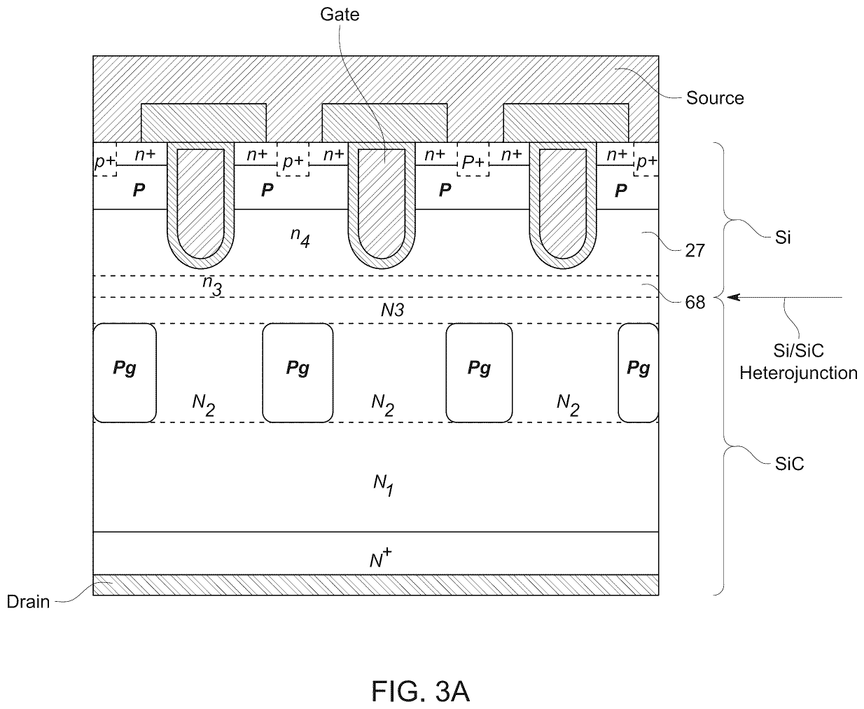

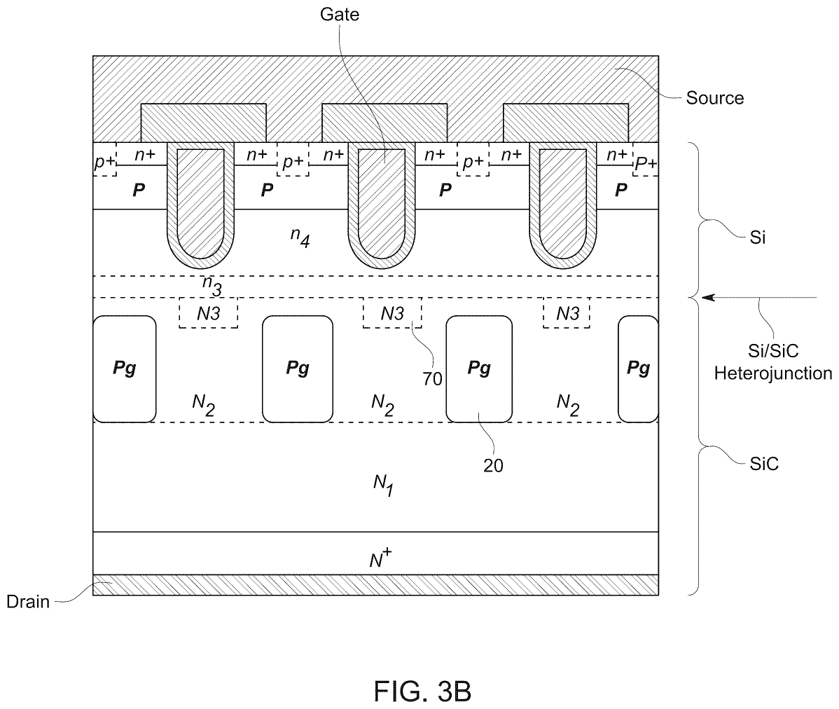

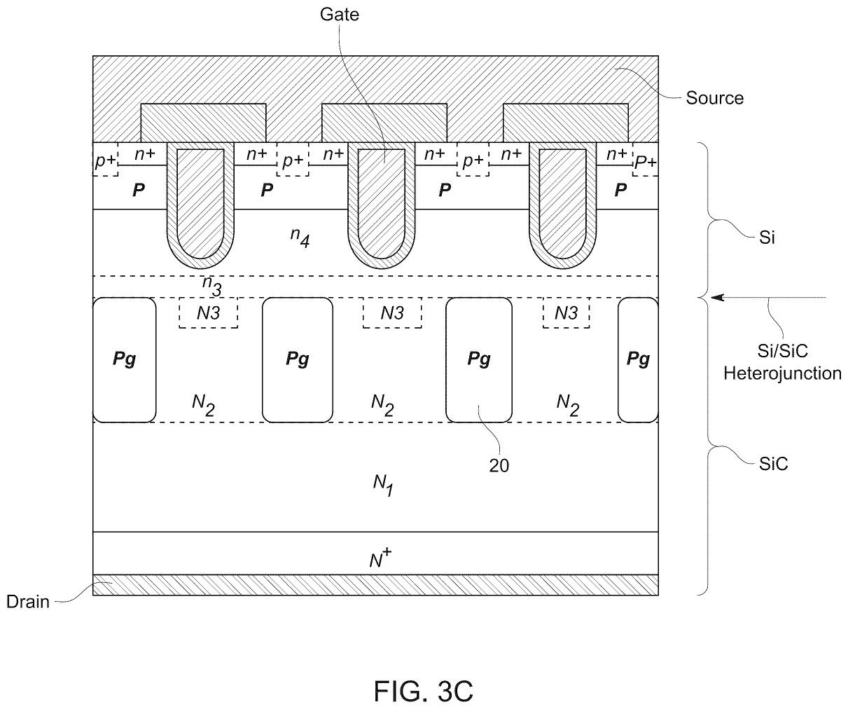

FIG. 3(a) shows a MOSFET structure similar to that shown in FIG. 1(a) but with an additional Si n-type layer 68, with a dopant concentration of n3, at the Si/SiC interface. The doping concentration of n3 is higher than that of the Si drift region 27. This reduces voltage drop.

FIG. 3(b) shows a MOSFET structure similar to that shown in FIG. 3(a) but with SiC N-type layer regions 70, with a dopant concentration of N3, that do not adjoin the P-type JFET gate regions 20.

FIG. 3(c) shows a MOSFET structure similar to that shown in FIG. 3(b) but with the top of the JFET gate regions 20 being at the Si/SiC heterojunction interface.

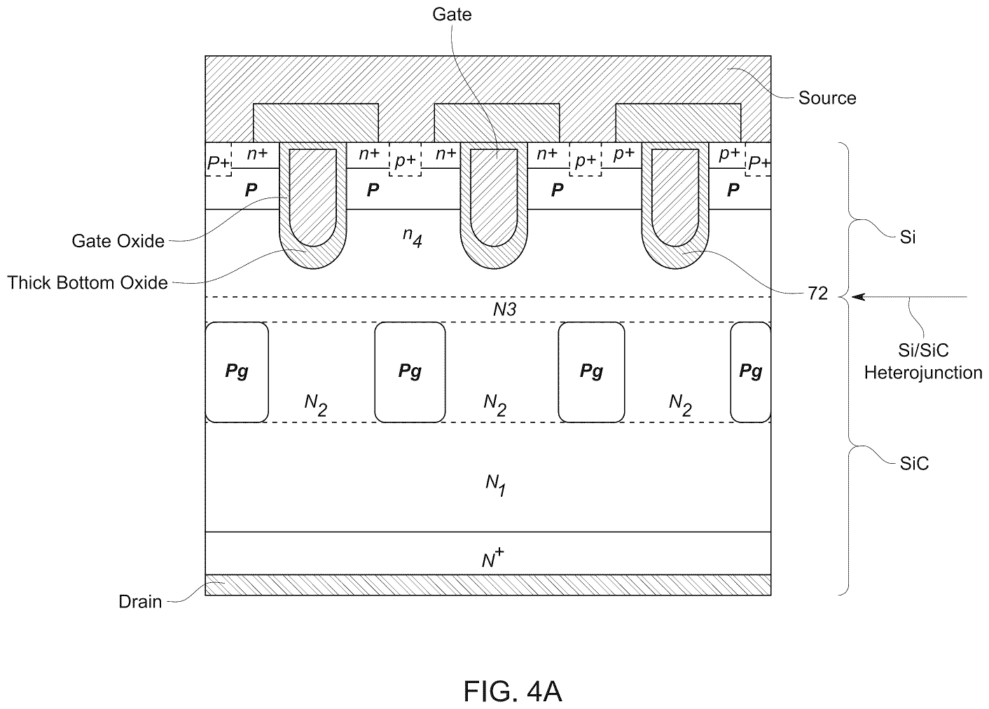

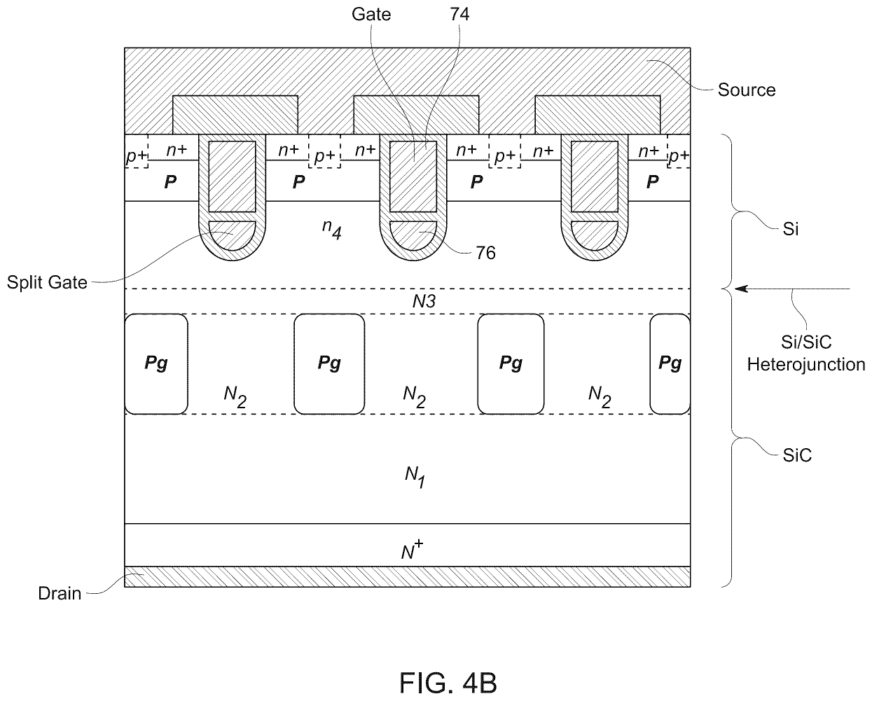

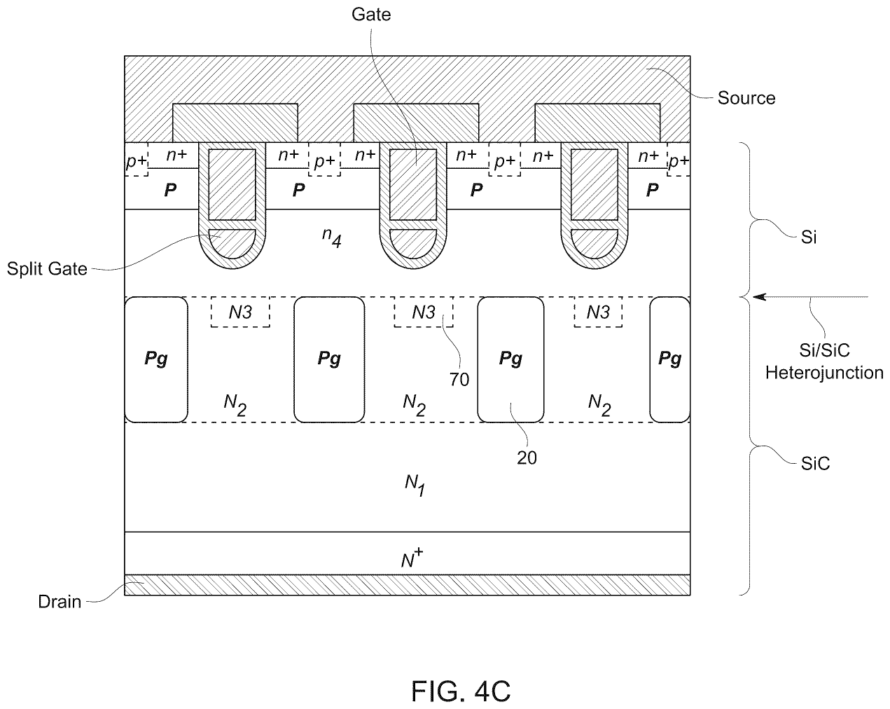

FIG. 4(a) shows a MOSFET structure similar to that shown in FIG. 1(a) but with a thick bottom-oxide 72 at the bottom of the trenches. This increases the oxide breakdown voltage at the bottom of the trenches.

FIG. 4(b) shows a MOSFET structure similar to that shown in FIG. 1(a) but with a split gate structure, where the top portion of the gate electrode 74 (polysilicon) can have a voltage different from the bottom portion of the gate electrode 76. This can be used to reduce the gate-drain capacitance and the possibility of gate oxide breakdown at the bottom of the trenches while freely controlling the channel conduction.

FIG. 4(c) shows a MOSFET structure similar to that shown in FIG. 4(b) but where the n-type layer 70 is segmented, and the JFET gate regions 20 extend to the Si/SiC interface.

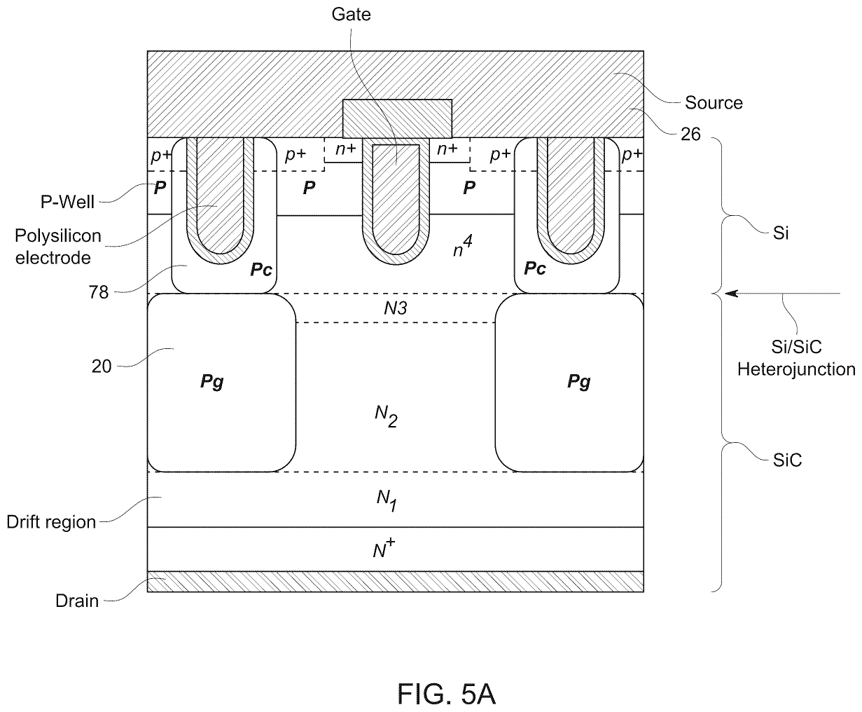

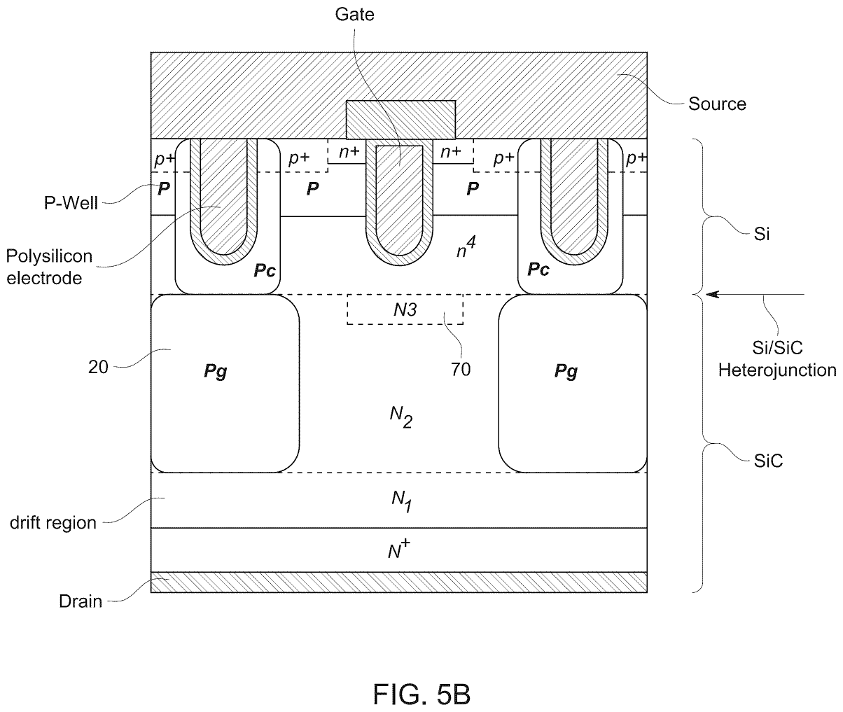

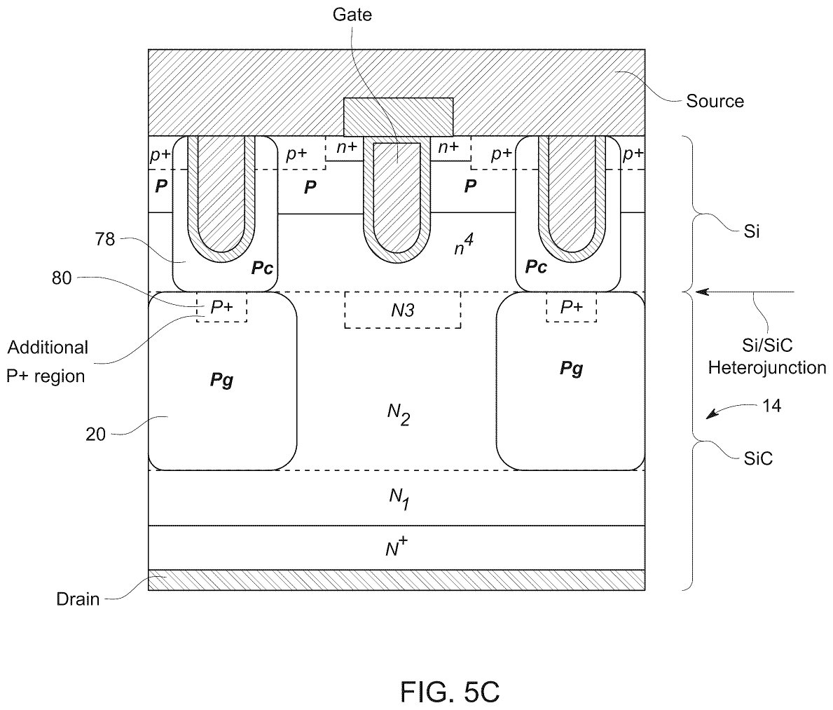

FIG. 5(a) illustrates an area of a MOSFET cell showing how the JFET gate regions 20 are shorted to the source metal 26 by a P+ contact region 78 (Pc) extending between the source metal 26 and the top of the JFET gate regions 20. This may be done with a deep p-dopant implant. Implanting though an empty trench eases the process. All JFET gate regions 20 are connected together outside the plane of the figure.

FIG. 5(b) shows a MOSFET structure similar to that shown in FIG. 5(a) but where the n-type layer 70 does not adjoin the JFET P-type gate regions 20.

FIG. 5(c) shows a MOSFET structure similar to that shown in FIG. 5(b) but with P+ contact regions 80 at the top of the P-type JFET gate regions 20 in the SiC layer 14 to improve the contact between the Pc contact regions 78 and the JFET gate regions 20.

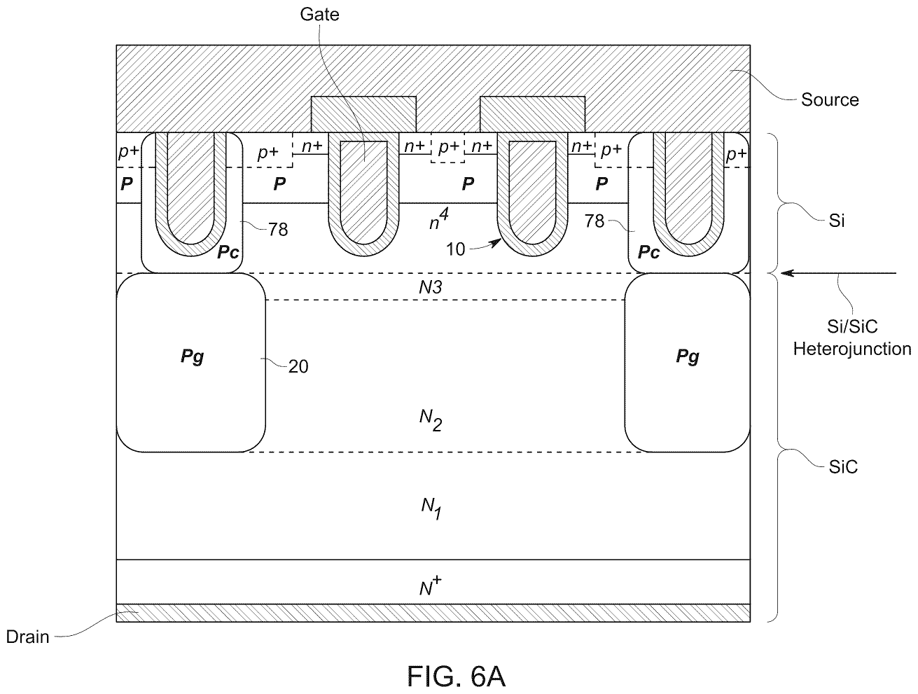

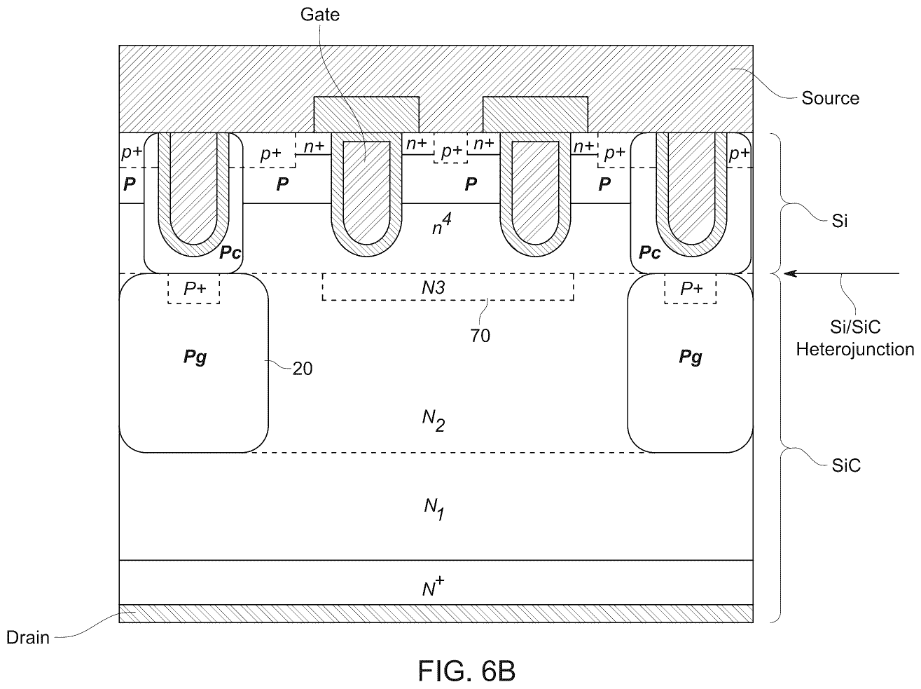

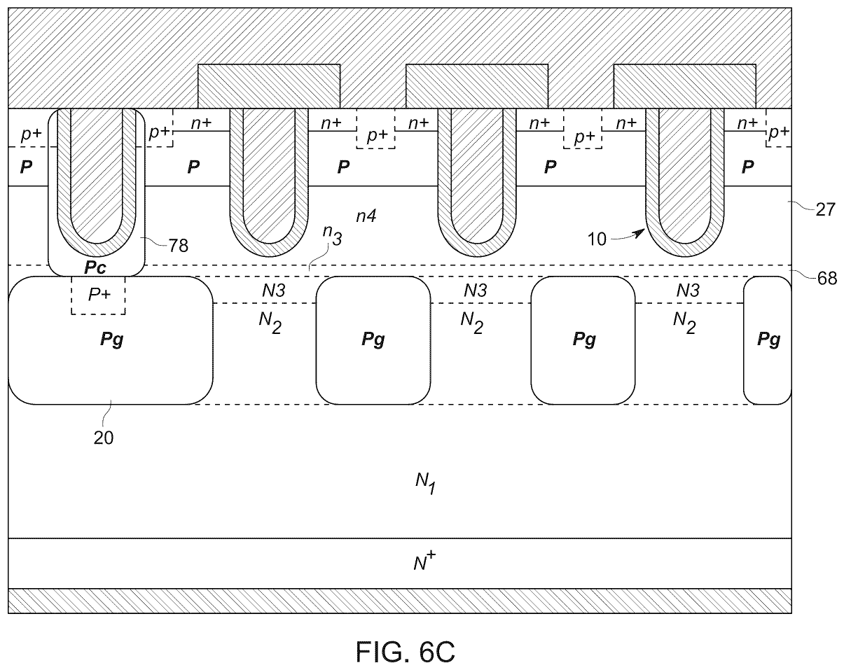

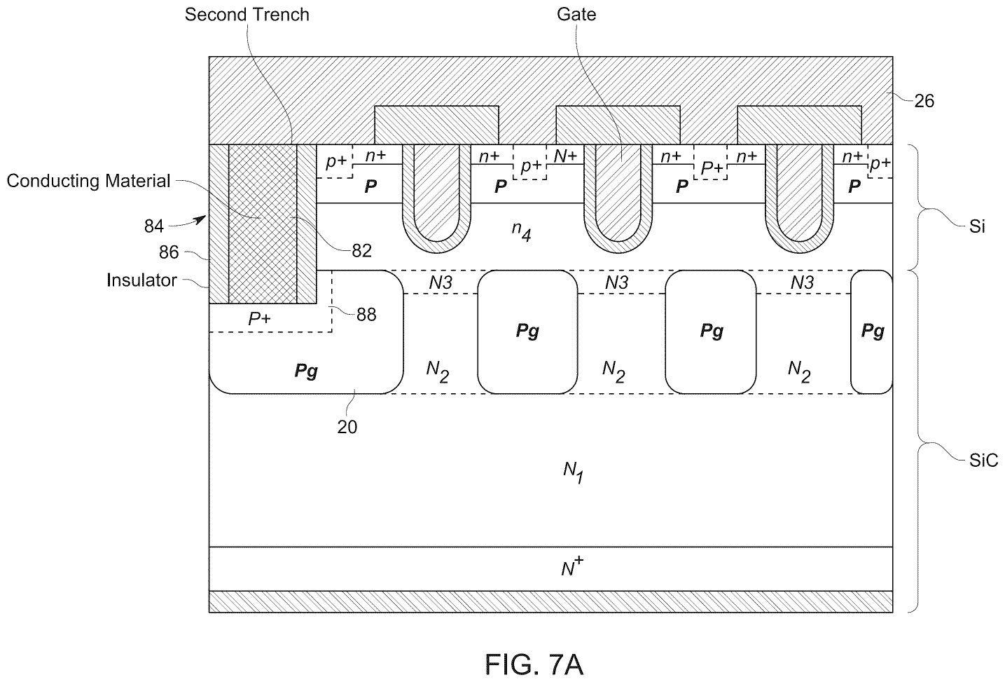

FIG. 6(a) shows a MOSFET structure similar to that shown in FIG. 5(a) but shows how any number of trench gates 10 can be surrounded by the P+ contact region 78 for the JFET gate regions 20.

FIG. 6(b) shows a MOSFET structure similar to that shown in FIG. 6(a) but where the n-type layer 70 has regions that do not adjoin the JFET P-type gate regions. 20.

FIG. 6(c) shows a MOSFET structure with a number of trench gates 10 surrounded by a P+ contact region 78 for the JFET gate regions 20 with an additional Si n-type layer 68. The dopant concentration n3 of the n-type layer 68 is higher than the dopant concentration n4 of the drift region 27.

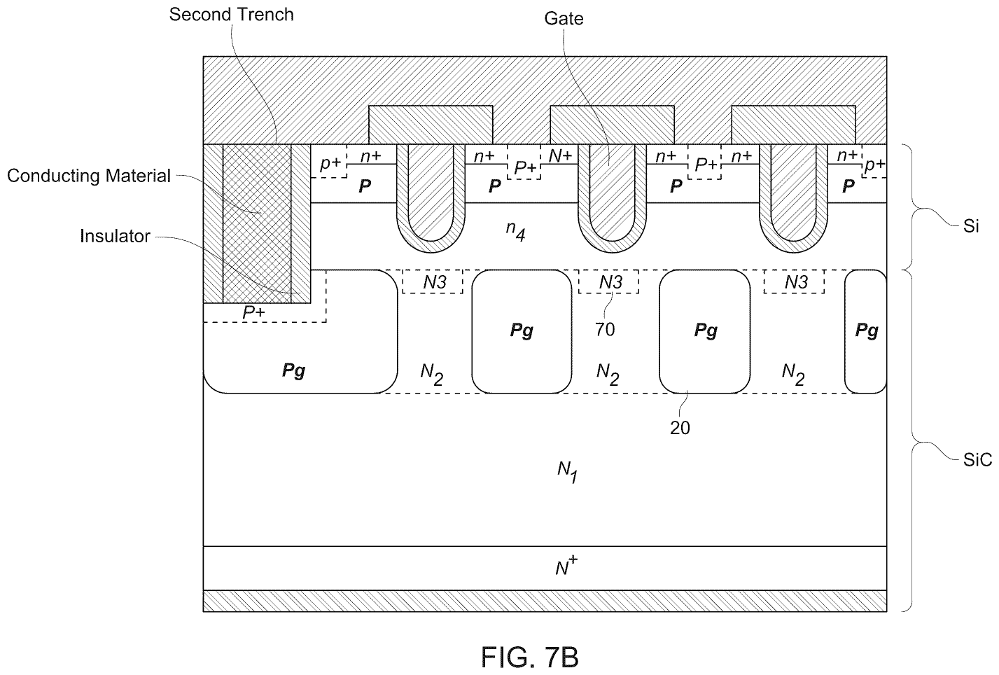

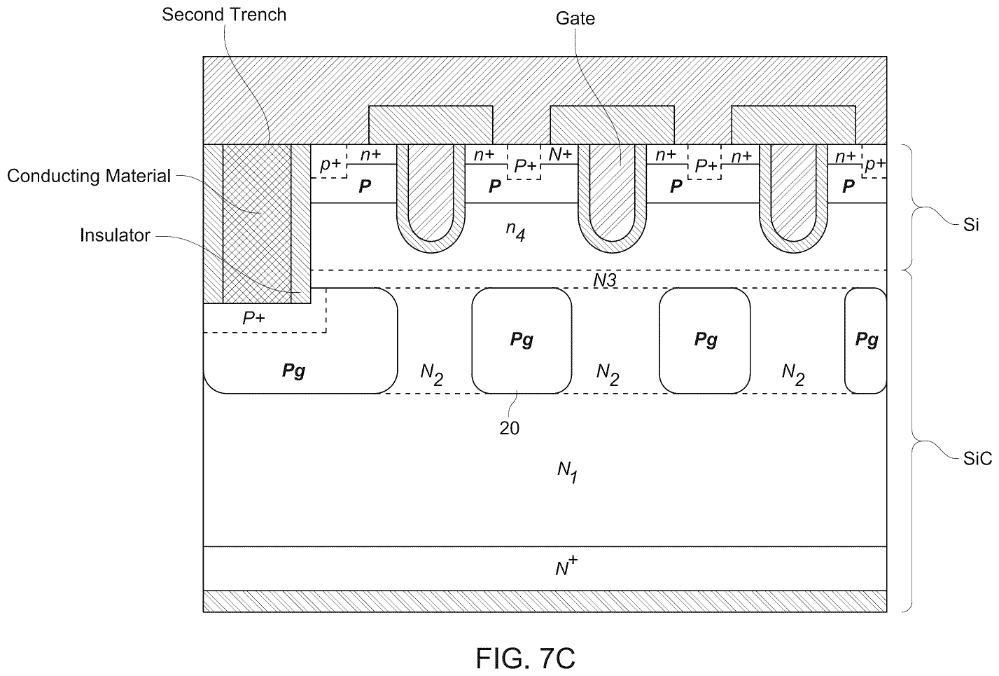

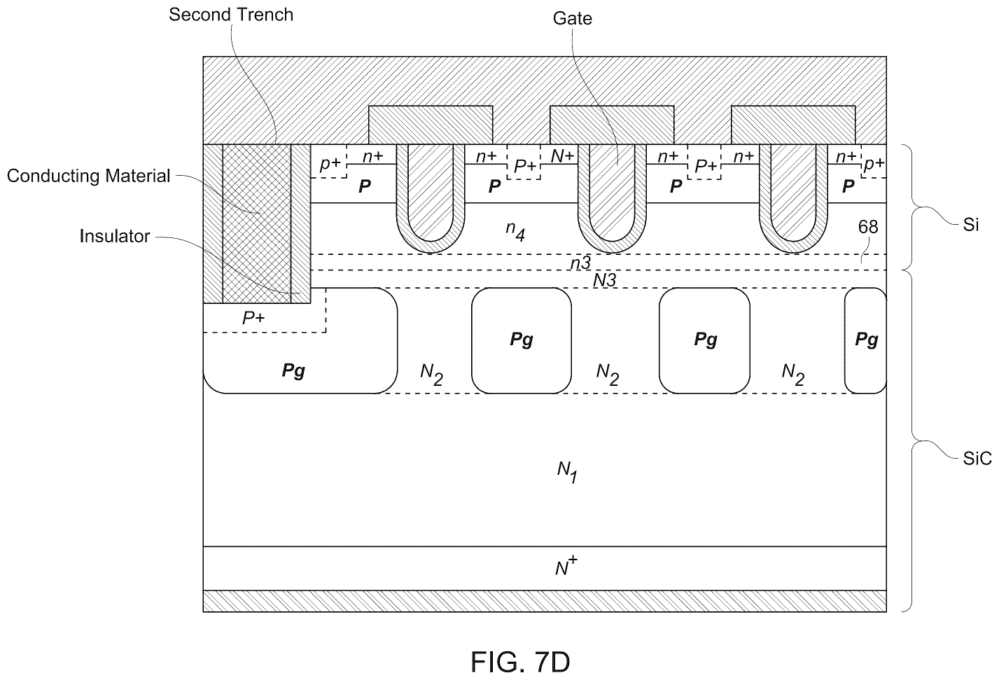

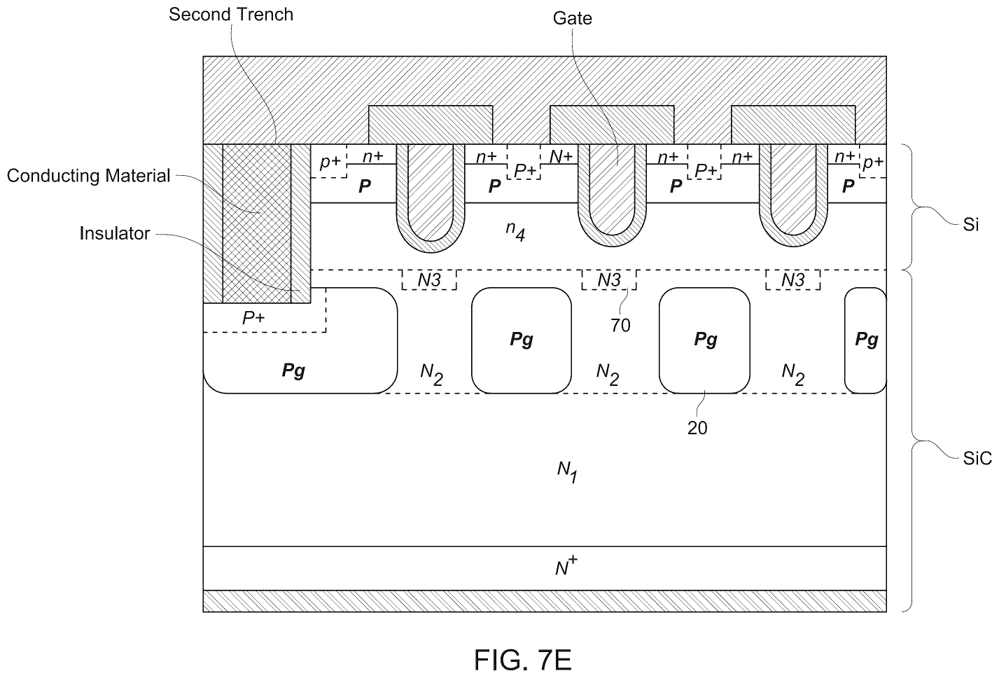

FIG. 7(a) illustrates how the JFET gate regions 20 can be connected to the source metal 26 by a conducting material 82, such as heavily doped polysilicon or tungsten, in a second trench 84 that is surrounded by a dielectric layer 86 such silicon dioxide (oxide). A P+ contact region 88 improves the electrical connection.

FIG. 7(b) shows a MOSFET structure similar to that shown in FIG. 7(a) but where the n-type layer regions 70 do not adjoin the JFET gate regions 20.

FIG. 7(c) shows a MOSFET structure similar to that shown in FIG. 7(a) but with the top of the JFET P-type gate regions 20 being below the Si/SiC heterojunction interface.

FIG. 7(d) shows a MOSFET structure similar to that shown in FIG. 7(c) but with an additional n-type layer 68 in the silicon.

FIG. 7(e) shows a MOSFET structure similar to that shown in FIG. 7(c) but where the n-type layer 70 has regions that do not adjoin the JFET P-type gate regions 20.

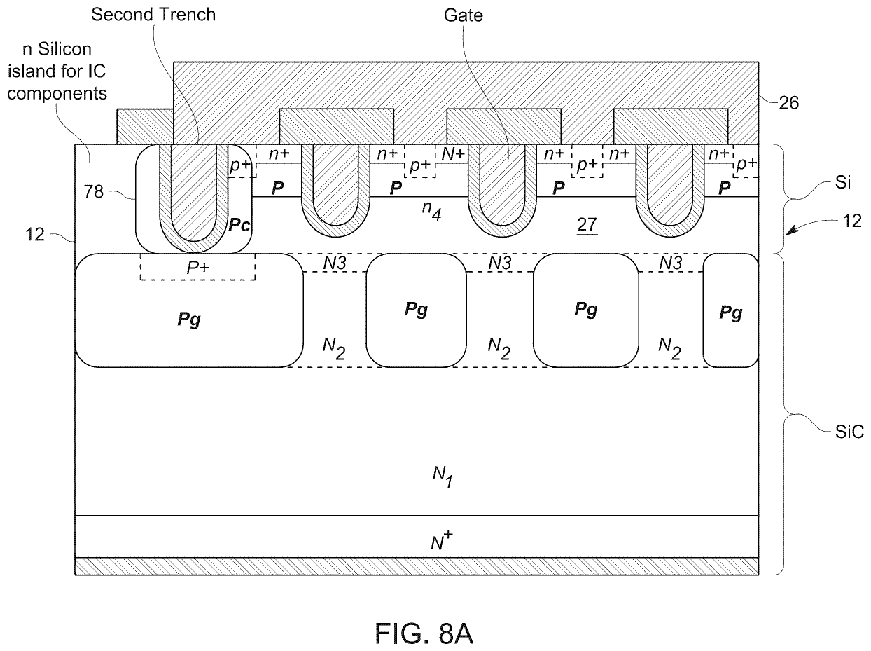

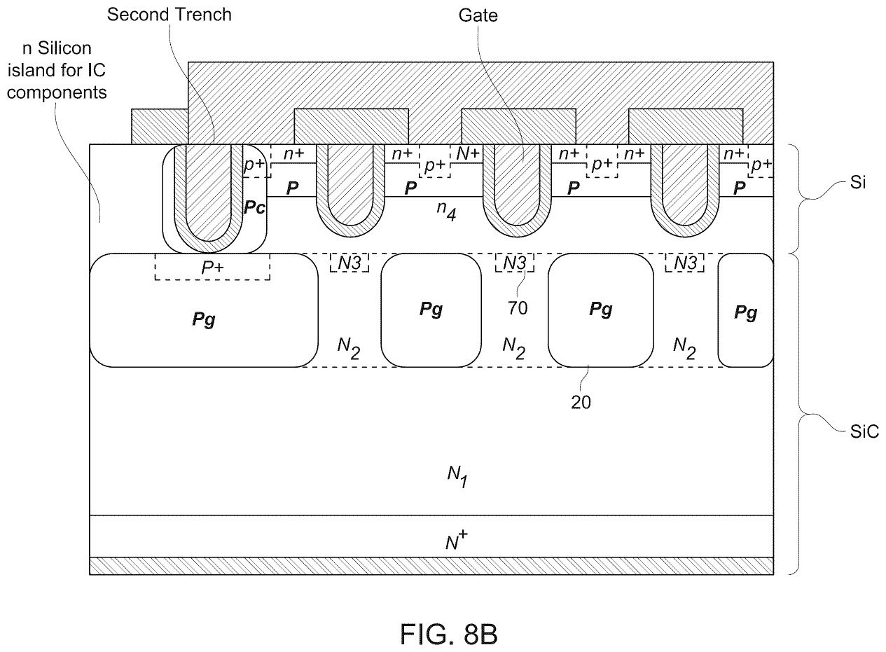

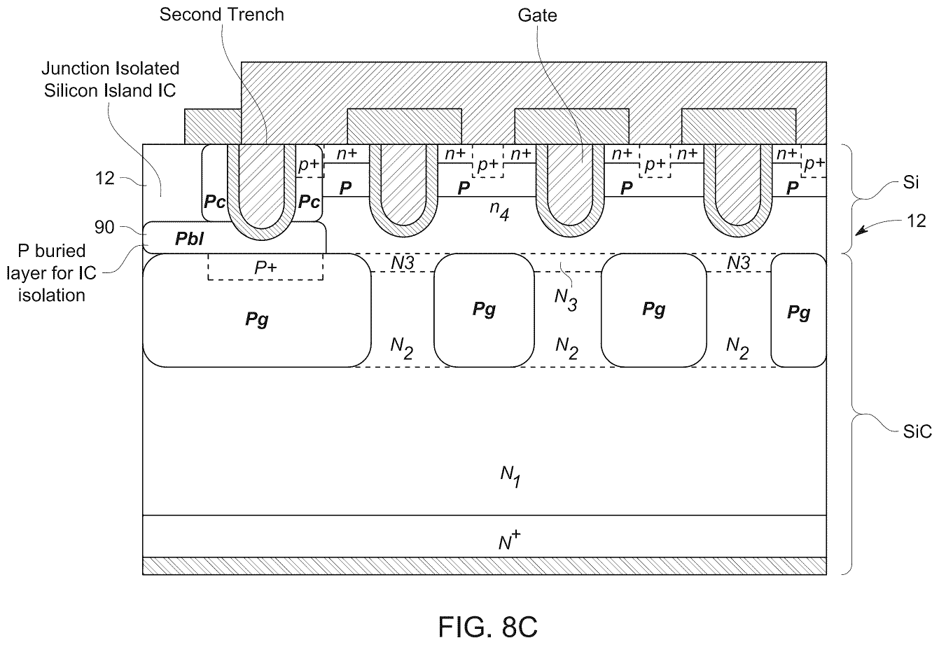

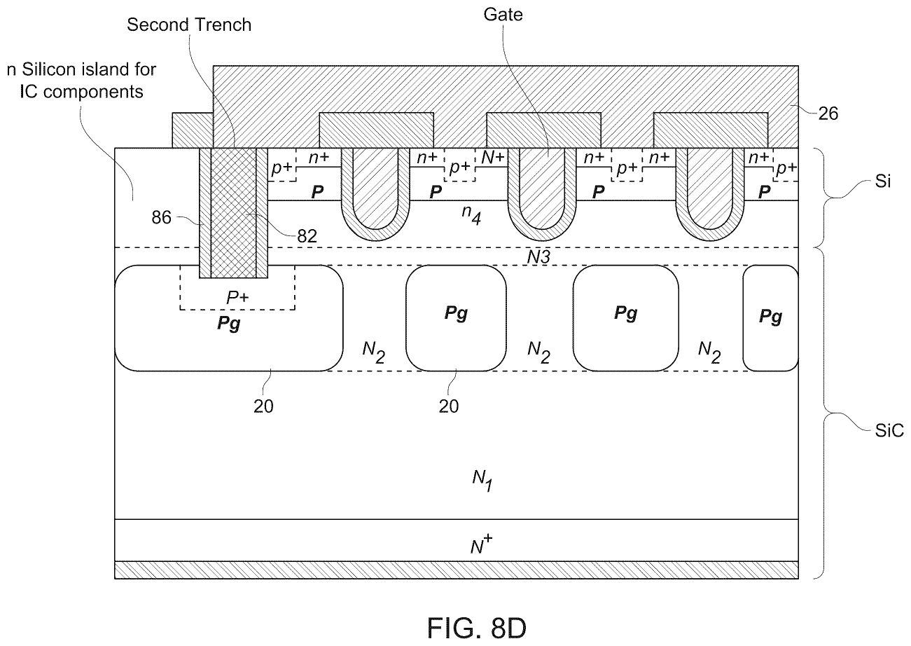

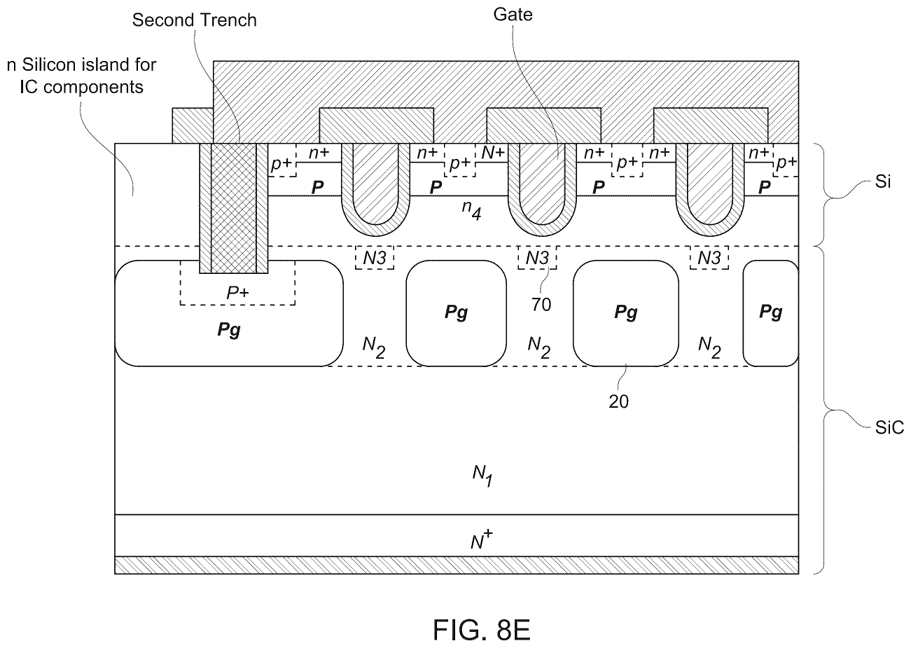

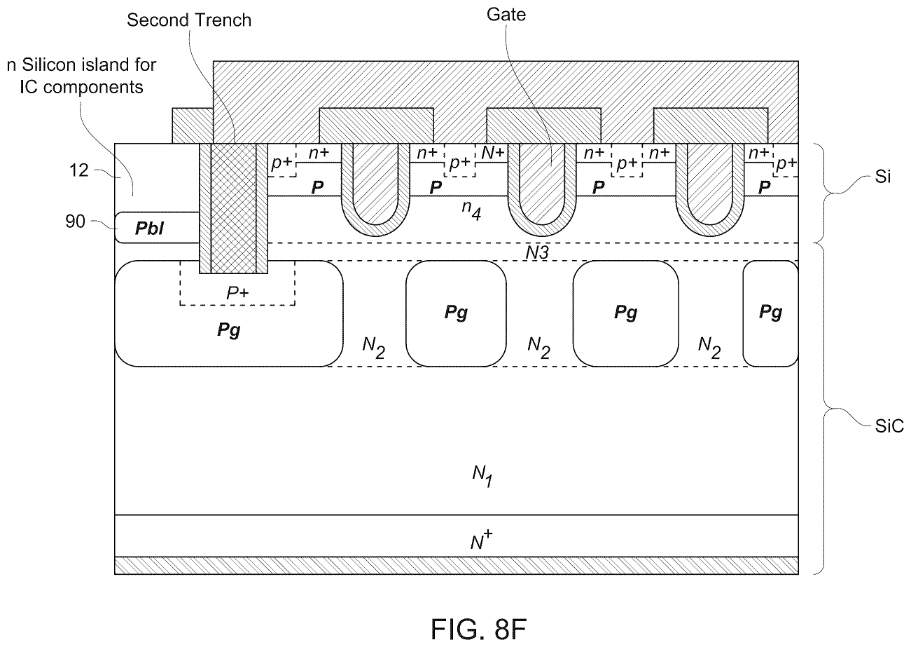

FIG. 8(a) illustrates how the vertical MOSFET can be only a portion of a die, where any other integrated circuit (IC) components can be formed in the n-type Si layer 12. The P+ contact region 78 isolates the MOSFET's Si drift region 27 from the rest of the Si layer 12. The source metal 26 only covers the MOSFET part of the die.

FIG. 8(b) shows a device similar to that shown in FIG. 8(a) but where the n-type layer 70 has regions that do not adjoin the JFET P-type gate regions 20.

FIG. 8(c) shows a device similar to that shown in FIG. 8(a) but shows a P-buried layer 90 (Pbl) for insulating the N-type Si layer 12 in the MOSFET area from the N-type Si layer 12 used for forming other integrated circuit (IC) components.

FIG. 8(d) shows a device similar to that shown in FIG. 8(a) but with the JFET gate regions 20 connected to the source metal 26 by a conducting material 82 in a second trench that is surrounded by a dielectric layer 86 such silicon dioxide (oxide), and the top of the JFET gate regions 20 being below the Si/SiC heterojunction interface.

FIG. 8(e) shows a device similar to that shown in FIG. 8(d) but where the n-type layer 70 has regions that do not adjoin the JFET P-type gate regions 20.

FIG. 8(f) shows a device similar to that shown in FIG. 8(d) but with a P-buried layer 90 (Pbl) that isolates the n-type Si layer 12 for other circuits.

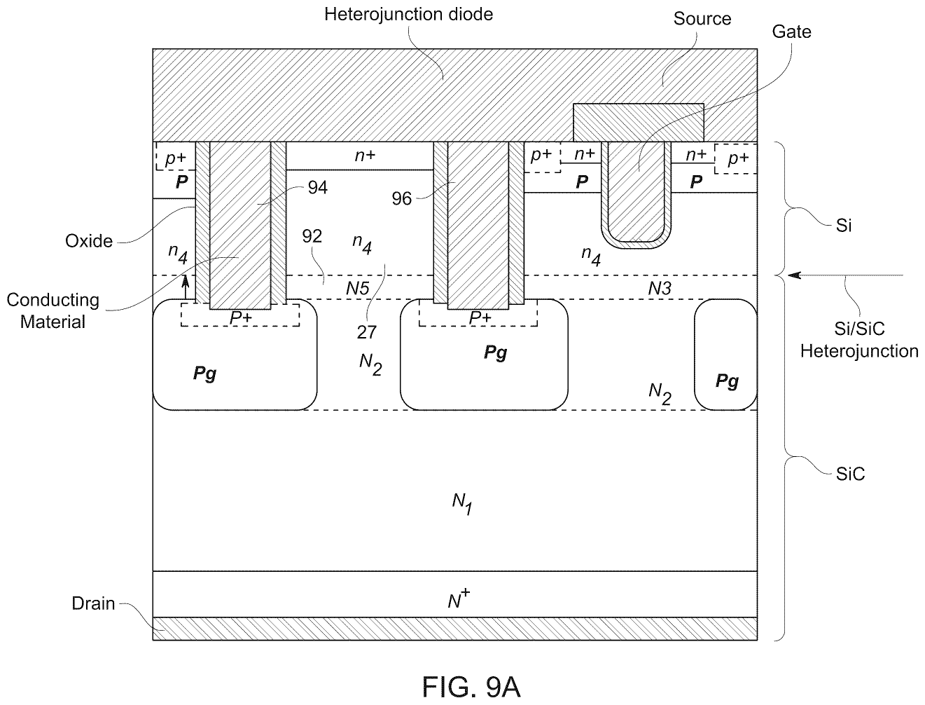

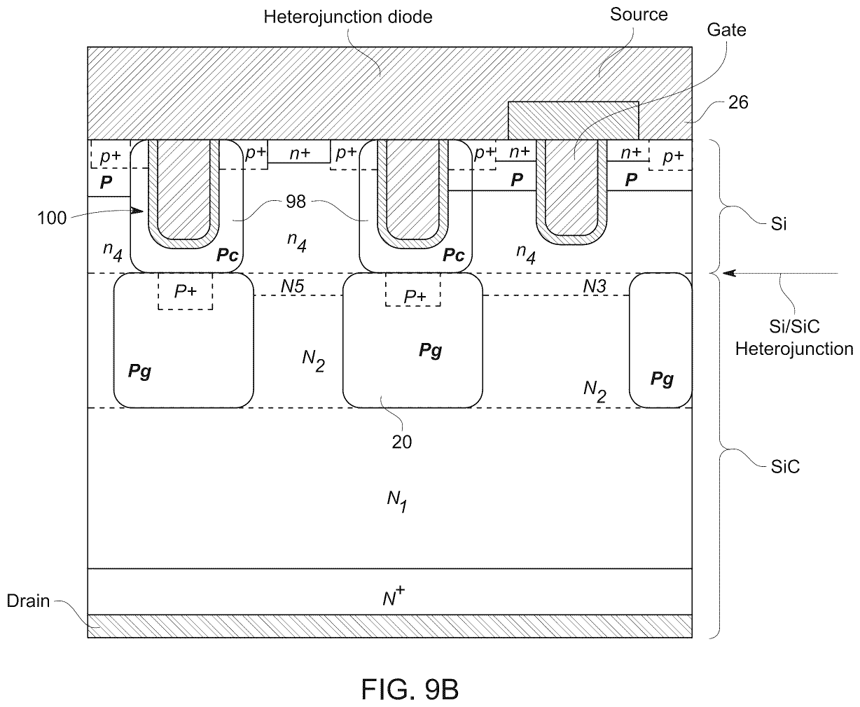

FIG. 9(a) shows a heterojunction diode formed by the Si drift region 27, with dopant concentration n4, and the SiC region 92, with dopant concentration N5, in parallel with the vertical MOSFET. The dopant concentration N5 is lower than the dopant concentration N3 and is used to adjust the conduction current-voltage characteristics. This rectification is due to the unequal bandgaps of the two N-type materials. The diode is isolated by the insulated conductors 94 and 96. The diode conducts a reverse current when the device is off, which may protect the MOSFET.

FIG. 9(b) shows a device similar to that shown in FIG. 9(a) but where the heterojunction diode is surrounded by a P+ contact region 98 (Pc) extending between the source metal 26 and the top of the JFET gate regions 20. The P+ contact region 98 is formed around trenches 100 that are not gate trenches. This enables the P+ contact region 98 to be implanted through an empty trench.

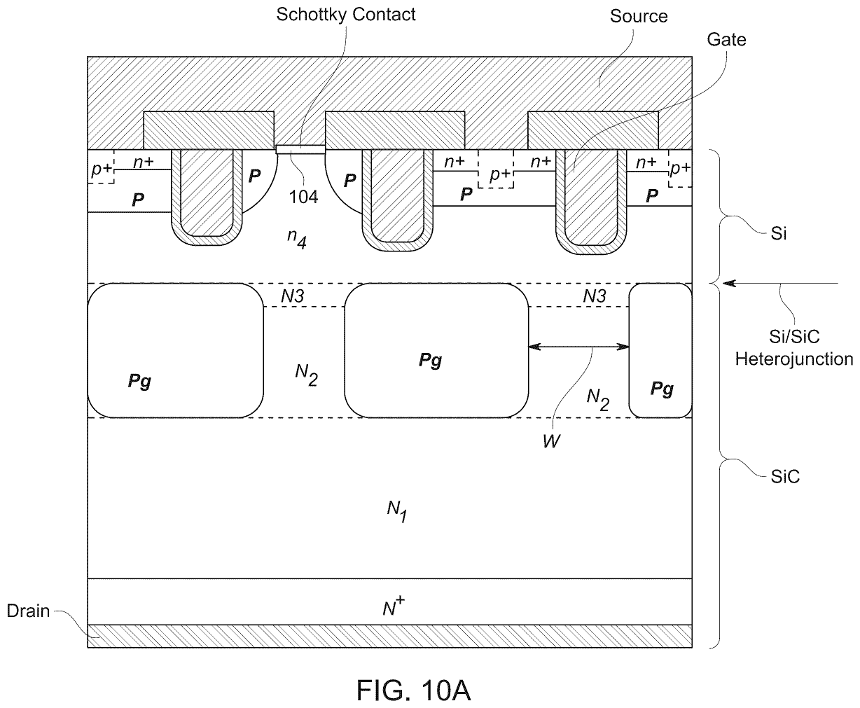

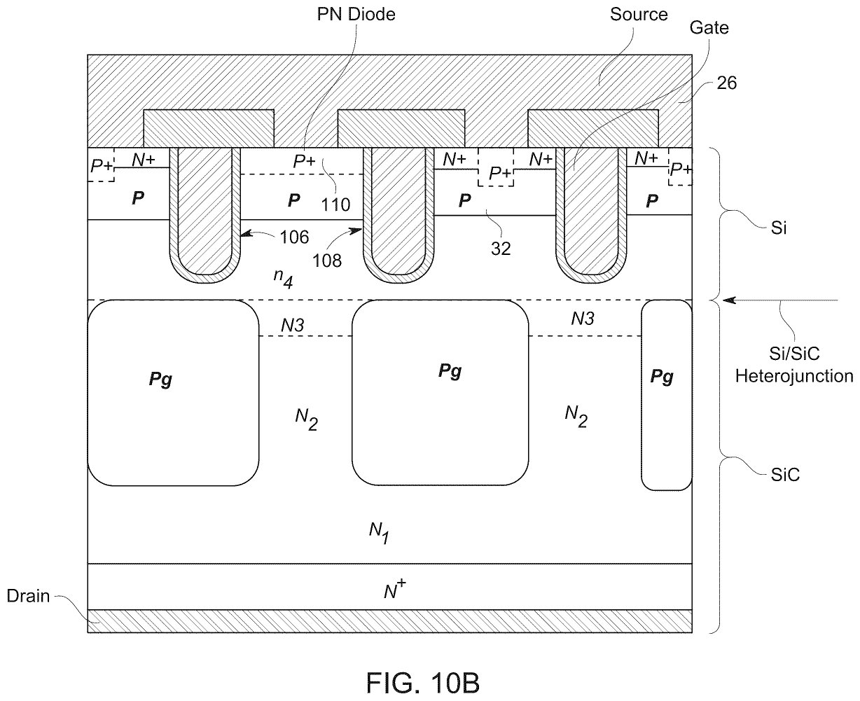

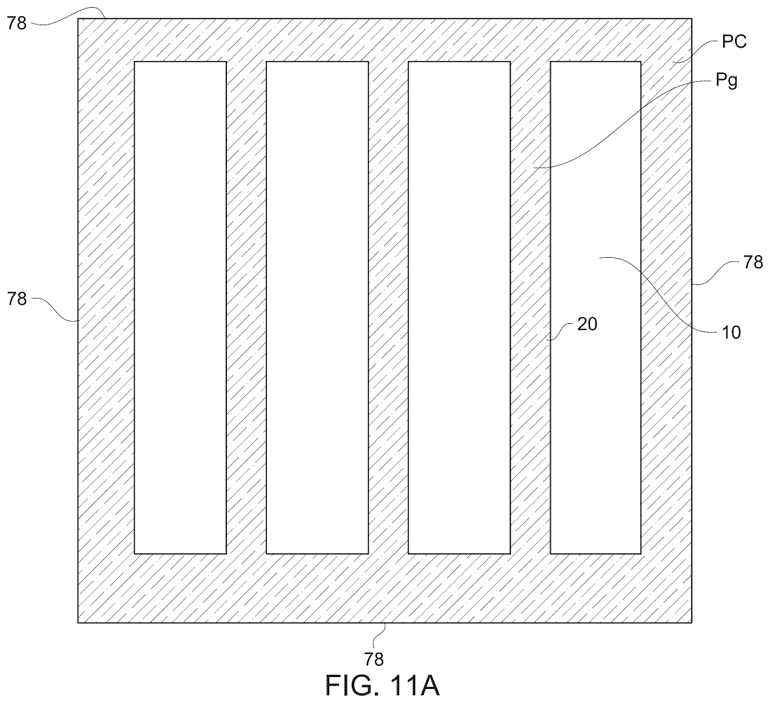

FIG. 10(a) shows a Schottky diode, using a conductive layer 104 as an anode, formed in parallel with a vertical MOSFET for conducting and reducing reverse recovery charge during third quadrant operation of the MOSFET.

FIG. 10(b) illustrates the formation of a PN diode between two gate trenches 106 and 108, in parallel with a MOSFET. A P+ contact region 110 is formed in the P-body region 32 and connects to the source metal 26 for conducting a reverse current. The PN diode can be contacted separately from the source metal 26 and used as a temperature sensor.

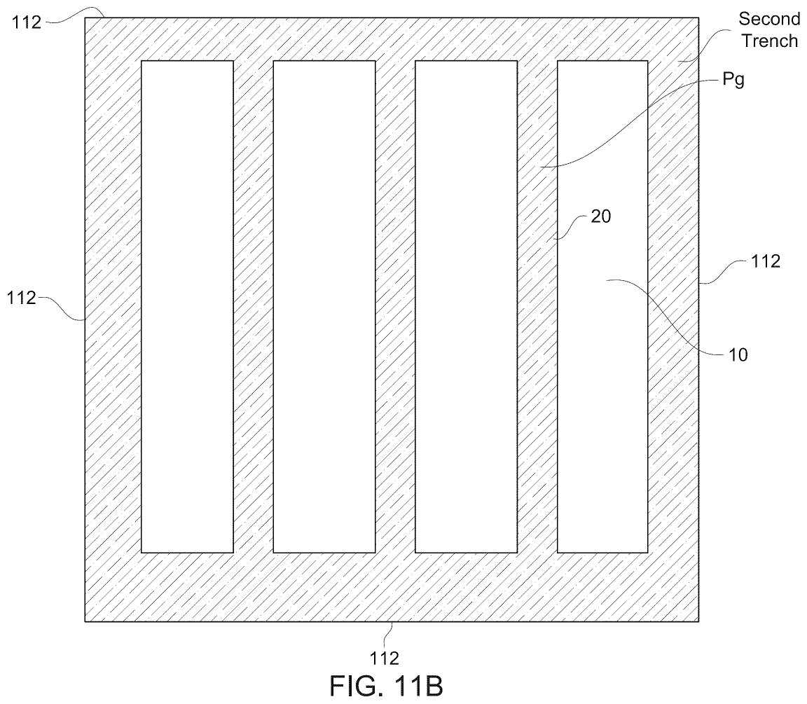

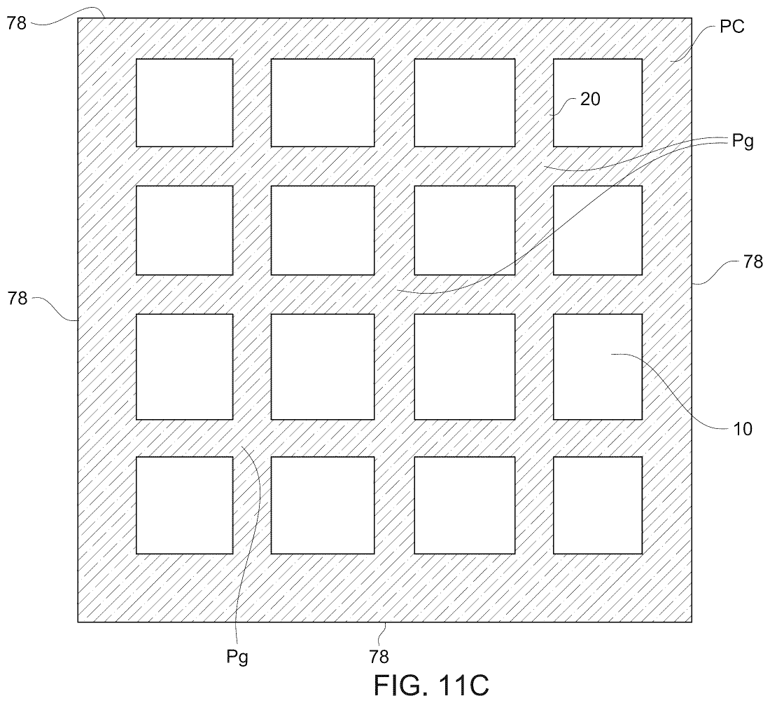

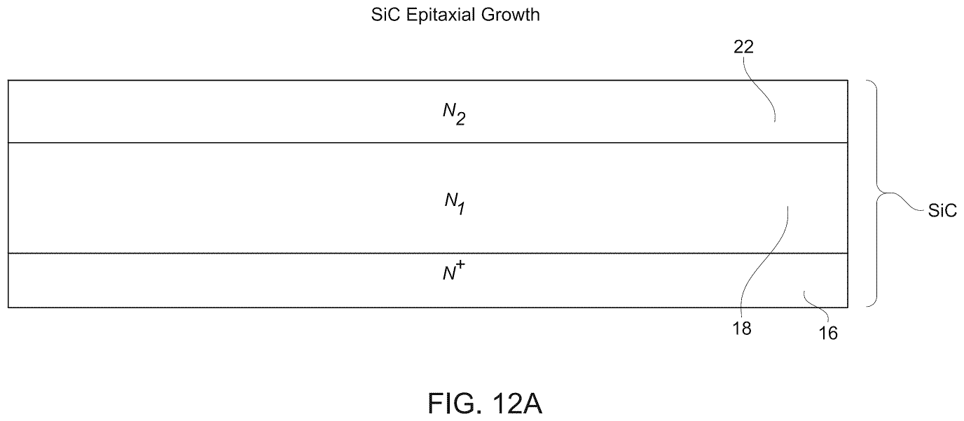

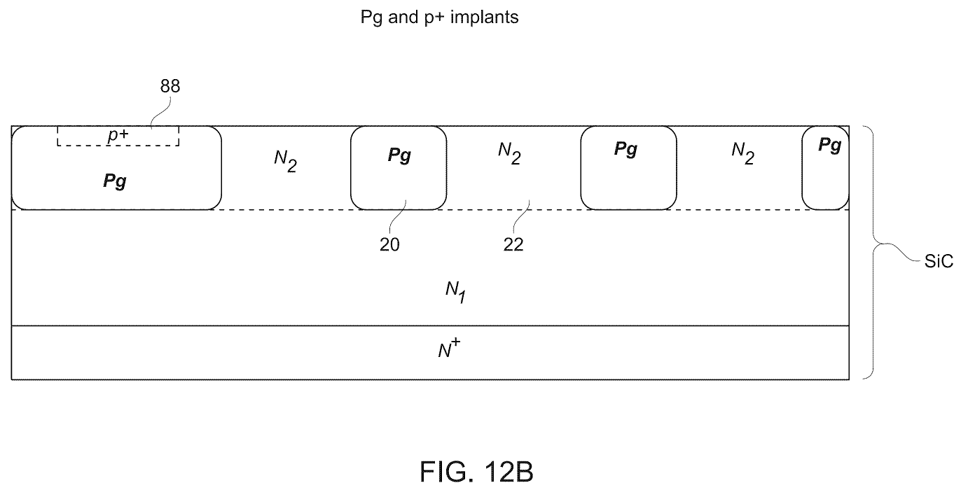

FIG. 11(a) illustrates a top-down view of strips of cells (containing trench gates 10) surrounded by the deep P+ contact region 78 of FIG. 6(a), for shorting the P-type JFET gate regions 20 (formed as vertical strips) to the source metal 26. The JFET gate regions 20 are between vertical strips of the trench gates 10.

FIG. 11(b) is similar to that shown in FIG. 11(a) but using a second trench 112, shown in FIG. 7(a), filled with insulated conductive material, to connect the JFET gate regions 20 of FIG. 7(a) to the source metal 26.

FIG. 11(c) illustrates a top-down view of rectangular cells (containing trench gates 10) surrounded by the deep P+ contact region 78 of FIG. 6(a), for shorting the JFET gate regions 20 to the source metal 26, and showing locations of the JFET gate regions 20 between the rectangular trench gates 10.

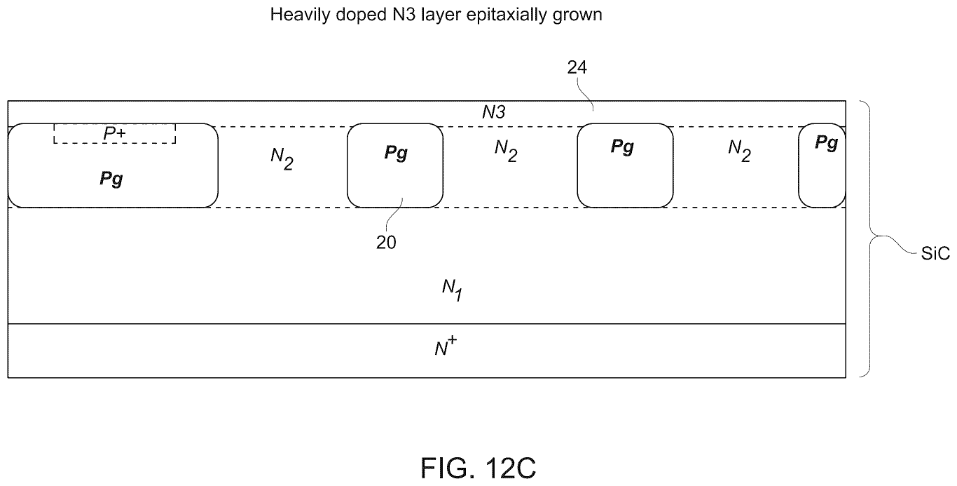

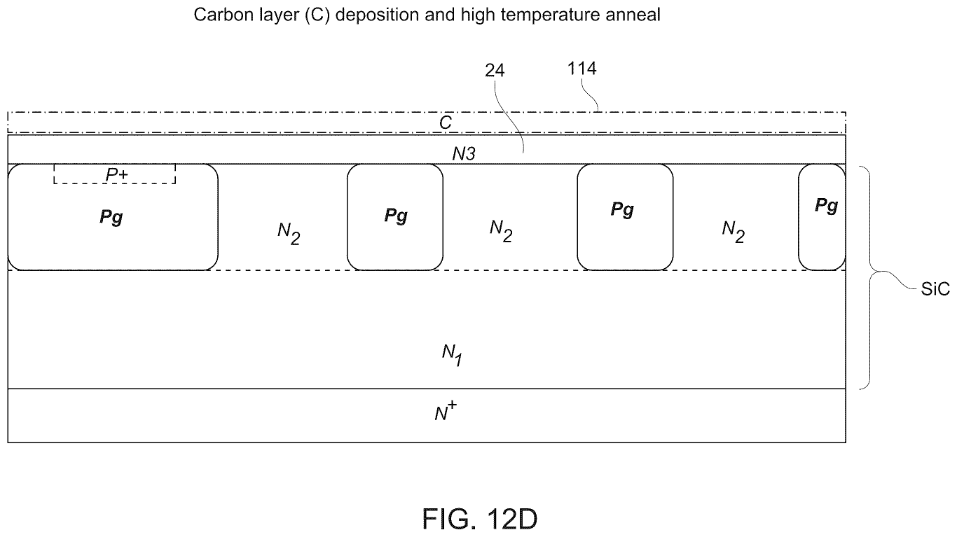

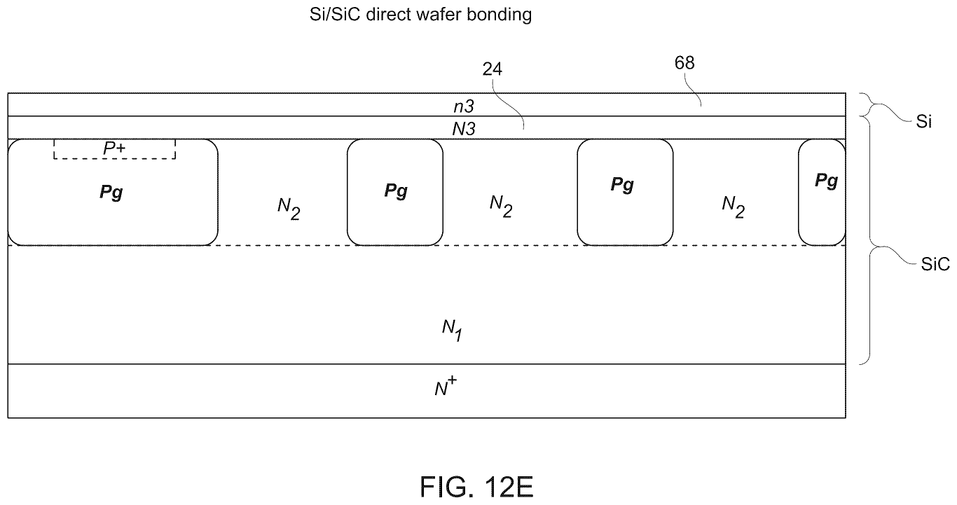

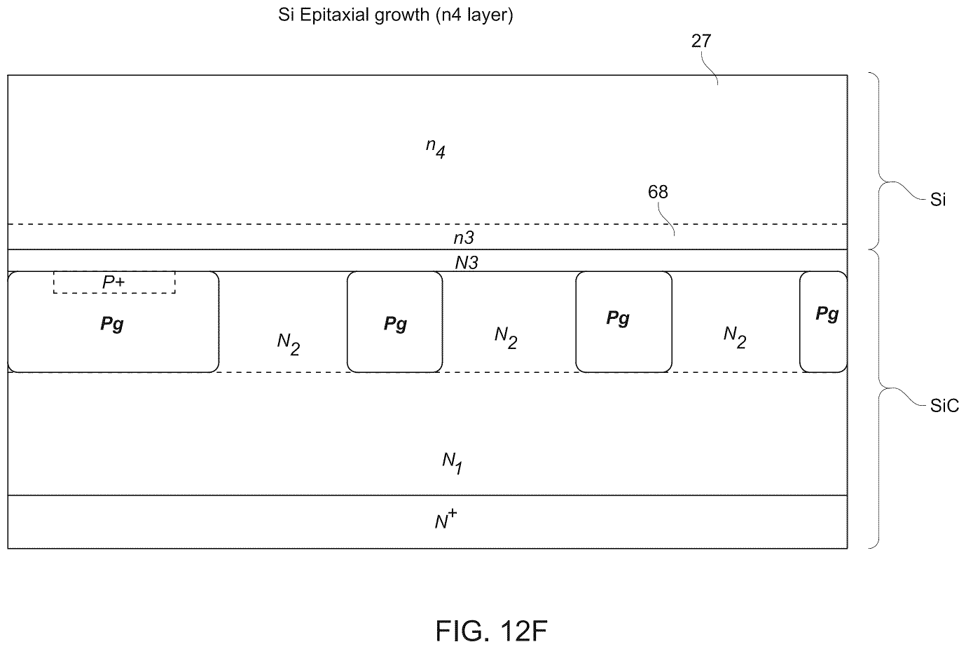

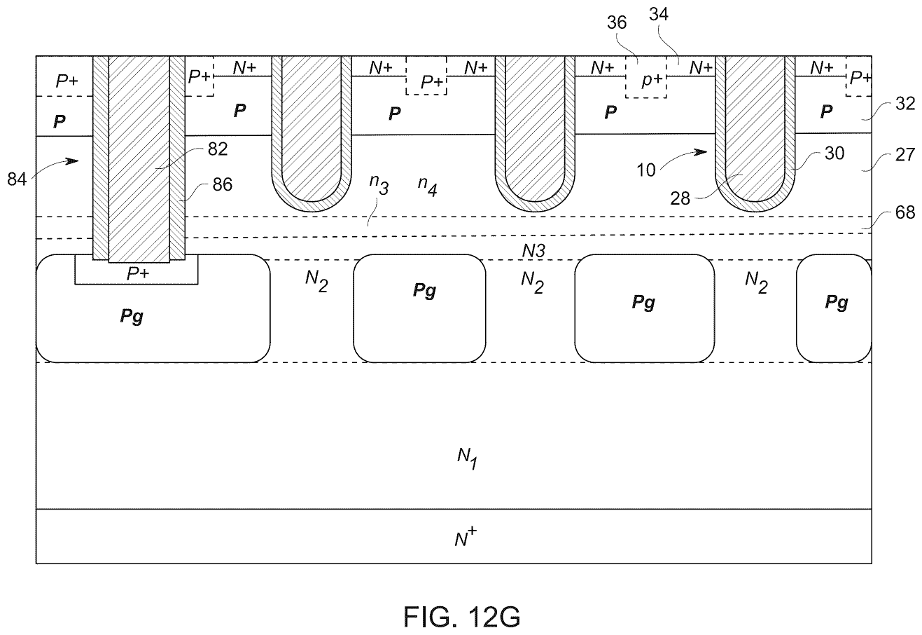

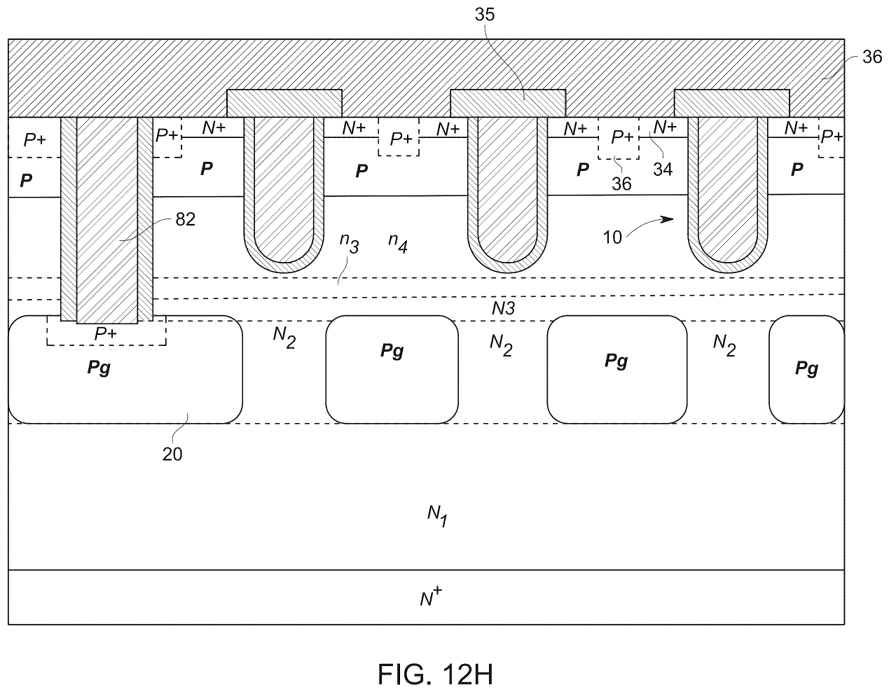

FIGS. 12(a)-12(h) illustrate process steps for forming the MOSFET embodiment of FIG. 7(d) which are easily adaptable to forming any of the other embodiments.

In FIG. 12(a) a starting N+ SiC substrate 16 has epitaxially grown over its top surface a drift layer 18 of dopant concentration N1. The substrate 16 can be monocrystalline SiC or a polycrystalline SiC. A thin N-type buffer layer of about 0.5 um may also be formed between layers 16 and 18. Over the drift layer 18 is grown a JFET channel region 22 of dopant concentration N2, where N2 is greater than N1. The particular dopant concentrations are determined by the desired performance characteristics, such as breakdown voltage. Simulations can be used to optimize the various region thicknesses and dopant concentrations.

In FIG. 12(b), the P-type JFET gate regions 20, with a dopant concentration of Pg, and a P+ contact region 88 are implanted. The gate regions 20 are all connected together outside of the plane of the figure, such as shown in FIGS. 11(a)-11(c).

In FIG. 12(c), a more heavily doped SiC N-type layer 24 is epitaxially grown or implanted, with a dopant concentration of N3. This will be the heterojunction enhanced tunnelling current layer for reduced voltage drop.

In FIG. 12(d), a carbon layer 114 is deposited on the n-type layer 24 and annealed at a high temperature.

In FIG. 12(e), a silicon substrate (or other Si layer), forming an N-type layer 68, with dopant concentration of n3, is wafer-bonded to the top of the SiC N3 layer, preferably at room temperature.

In FIG. 12(f), a second drift region 27, with a dopant concentration of n4, is epitaxially grown over the Si N-type layer 68.

In FIG. 12(g), trenches are formed in the surface using RIE. The surfaces of the trench gates 10 are oxidized to form gate oxide 30, and a dielectric layer 86, which may also be an oxide, is formed on the second trench 84. The trench gates 10 are filled with a doped polysilicon to form gate electrodes 28, and a metal or polysilicon conductor 82 fills the second trench 84. A P-type body region 32 is formed by dopant implantation and drive-in. N+ source regions 34 are then implanted, followed by the implantation of P-type dopants to form P+ body contact regions 36.

In FIG. 12(h), a dielectric layer 35 is patterned to insulate the tops of the trench gates 10. A second trench containing insulated conductive material 82, for contacting the JFET gate regions 20, is formed. A source metal 26 is then deposited over the surface to contact the source regions 34 and P-body contact regions 36. As shown in FIG. 7(d), a bottom drain metal 40 is formed on the bottom surface. The SiC wafer bottom surface may be thinned before forming the drain metal 40.

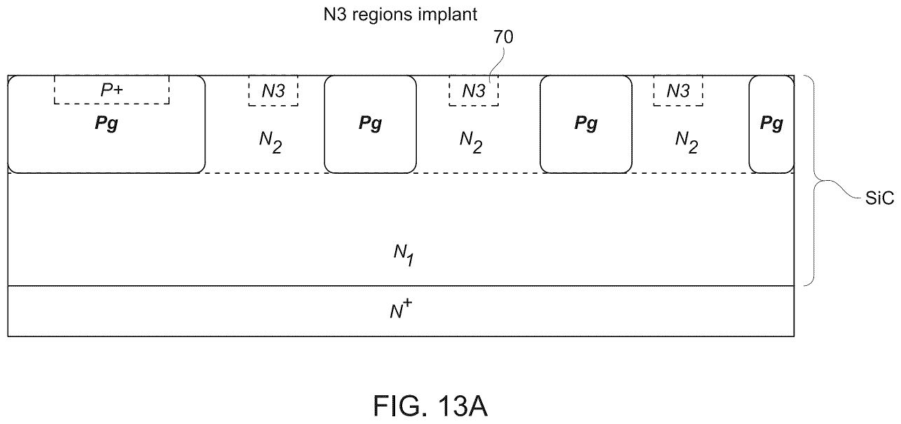

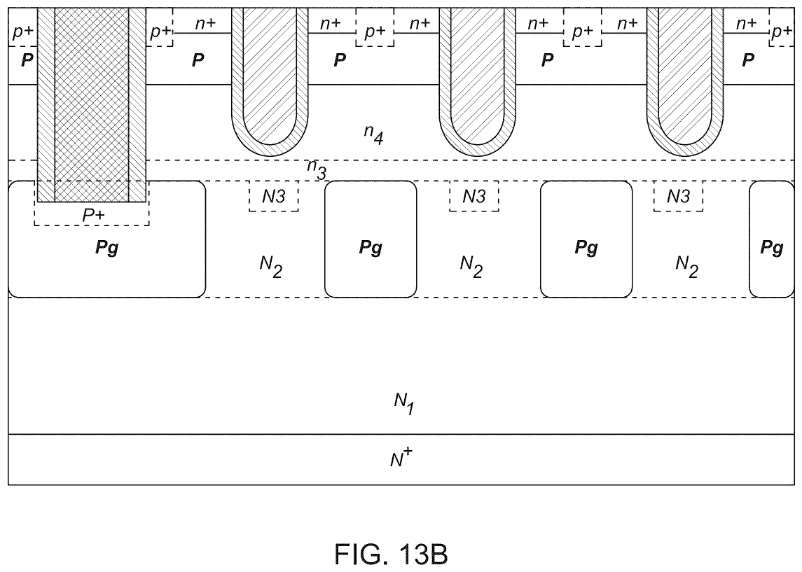

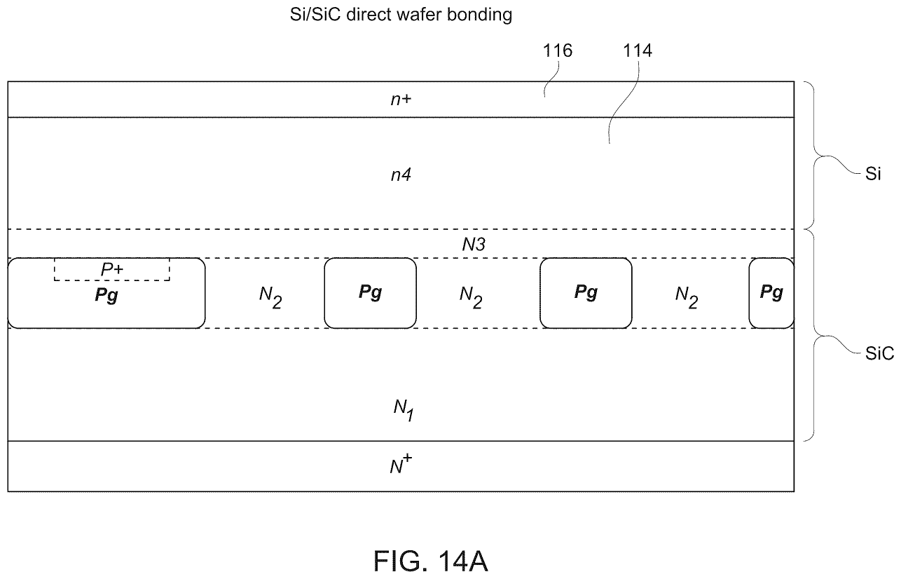

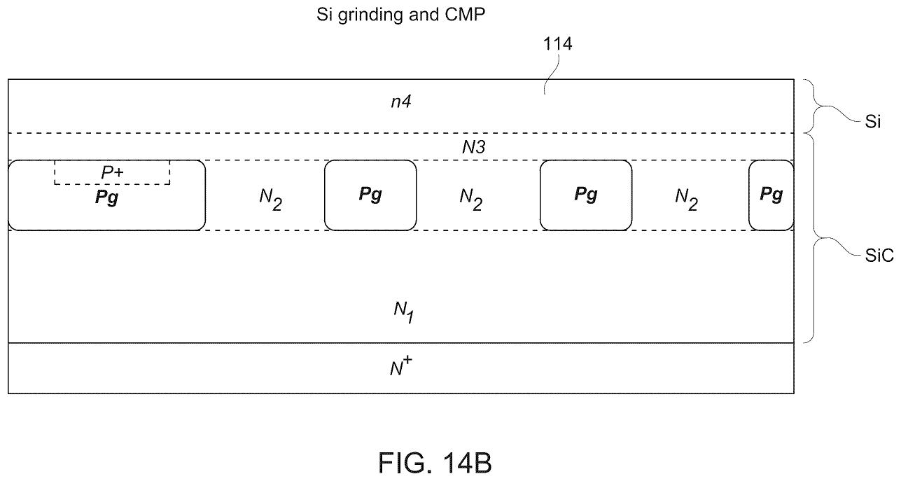

FIG. 13(a) and FIG. 13(b) show alternative steps of forming a device with an N3 layer that does not adjoin the JFET gate regions.

In FIG. 13(a), as an alternative to FIG. 12(c), the SiC n-type layer 24 of FIG. 12(c) is replaced by separate regions 70, by dopant implantation, with a dopant concentration of N3. The N3 concentration is greater than 1×10E18 cm⁻³. This lowers voltage drop.

In FIG. 13(b), the remainder of the device is formed as previously described with respect to FIGS. 12(d) to 12(g).

FIG. 14(a) and FIG. 14(b) show an alternative method of direct bonding of Si and SiC wafers using a Si wafer with an n-type epitaxial layer 114, having a dopant concentration of n4, and a N+Si substrate 116. As shown in FIG. 14(b), after direct bonding, the Si substrate 116 is removed by grinding and chemical mechanical polishing (CMP).

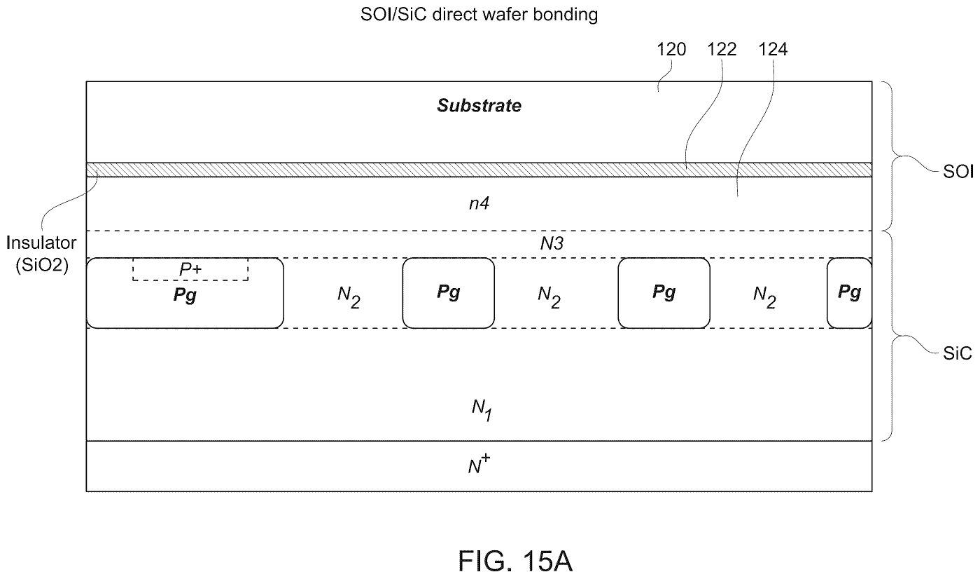

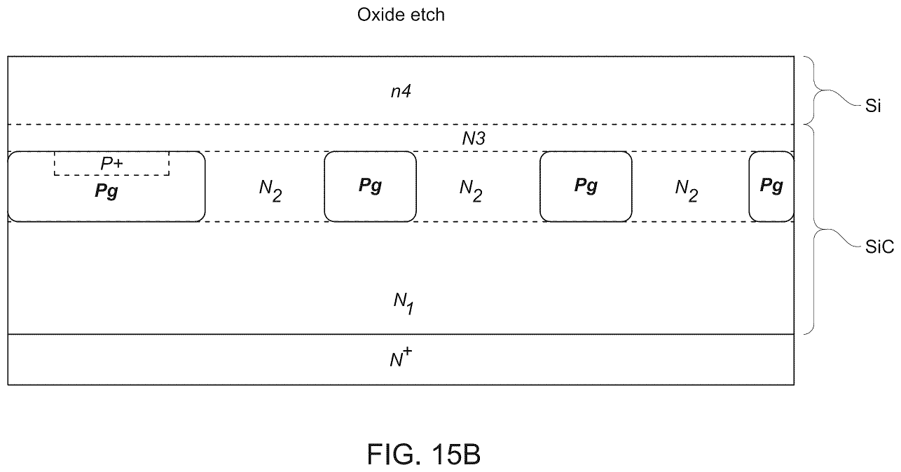

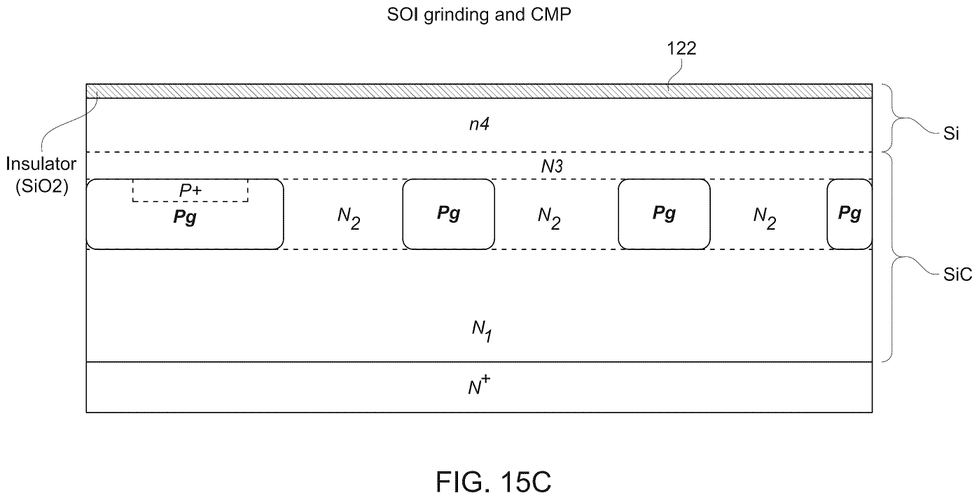

FIGS. 15(a)-(c) show an alternative method of direct bonding using a Silicon-on-Insulator (SOI) wafer with the desired epi thickness and doping.

In FIG. 15(a), a substrate 120 has an oxide layer 122 formed on its surface. A silicon N-type layer 124 is then formed over the oxide layer 122, and the surface of the N-type layer 124 is bonded to the surface of the SiC wafer.

In FIG. 15(b), the substrate 120 is removed by wet etching the oxide layer 122. The remaining steps have been previously described.

In FIG. 15(c), the substrate 120 is alternatively removed by grinding and CMP followed by etching the oxide layer 122.

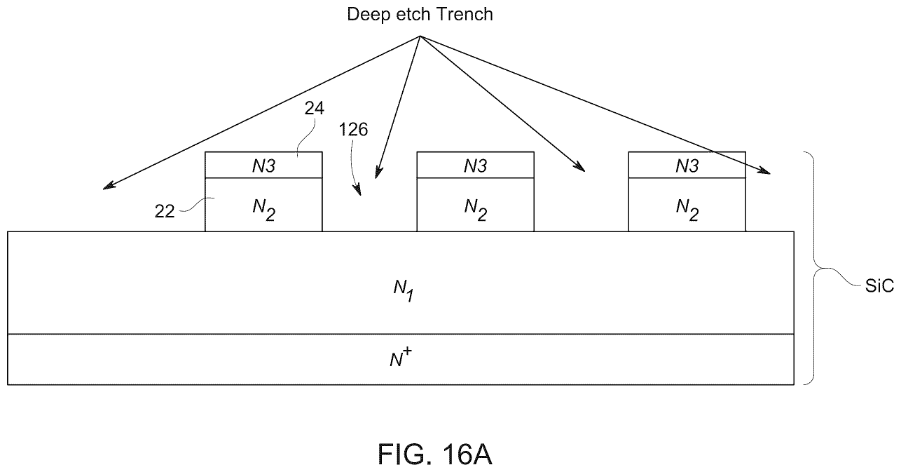

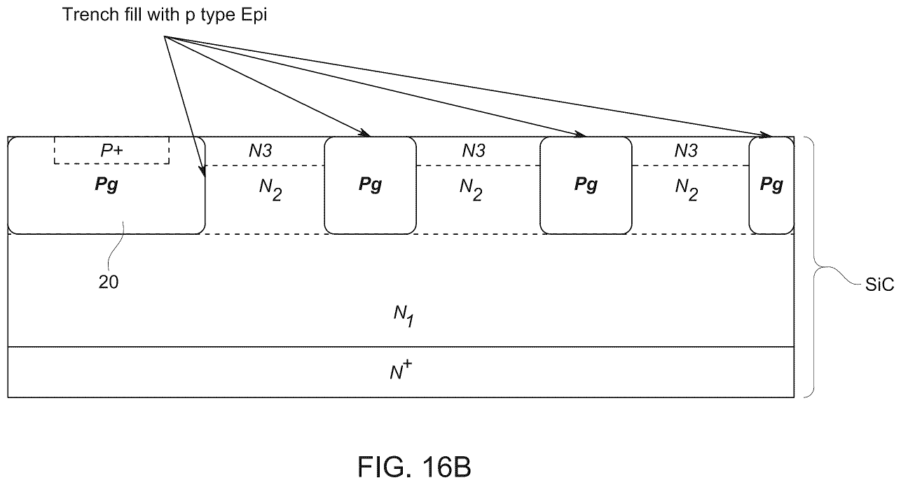

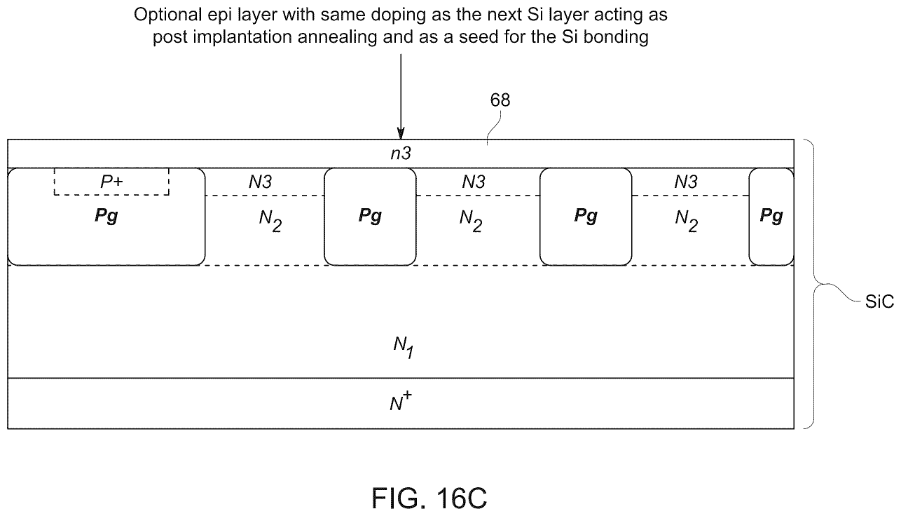

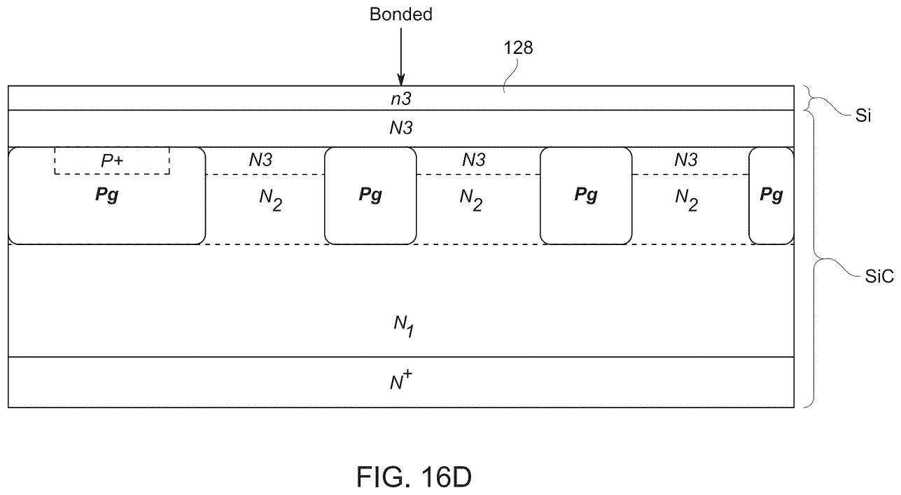

FIGS. 16(a)-(d) show a method of forming the P-type JFET gate regions using trenches. In FIG. 16(a), after the JFET channel regions 22 and n-type layer 24 are formed, the layers are etched to form trenches 126.

In FIG. 16(b), p-type SiC is epitaxially grown in the trenches 126 to form the JFET gate regions 20.

In FIG. 16(c), a SiC n-type layer 68, with a dopant concentration of N3, is grown over the SiC surface. The dopant concentration may be the same as the Si wafer to be bonded to it. Forming the n-type layer 68 is used for post implantation annealing and as a seed for the Si wafer bonding.

In FIG. 16(d), an Si wafer 128, having a dopant concentration of n3, is bonded to the SiC surface. The remaining steps have been previously described.

The dopant types can be reversed for a P-channel MOSFET.

The SiC material may instead be GaN.

The disclosed structure provides the advantages of higher breakdown voltage, lower specific on-resistance, higher thermal conductivity of the SiC material, higher MOS channel mobility, higher reliability carbon-free gate oxide, ease of gate drive of the silicon material, and other advantages. The thin Si/SiC heterojunction conduction band barrier, due to the thin highly doped n-type layer 24 in FIG. 1(a), results in a significant enhancement of the tunneling current that flows through the barrier. The high tunneling current lowers the voltage drop across the heterojunction in the MOSFET's on-state.

While the figures shown in this disclosure are not to scale but are qualitatively correct, the geometries used in practice may differ and should not be considered a limitation in any way. It is understood by those of ordinary skill in the art that the actual layout will vary depending on the specifics of the implementation, and any depictions illustrated herein should not be considered a limitation in any way.

It is also understood that numerous combinations of the above embodiments can be realized. All the above variants of the structure can be realized in stripe or cellular layout such as square, rectangular, hexagonal, or circular layouts.

While embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A heterojunction semiconductor device structure, comprising:
a first semiconductor layer of a first bandgap semiconductor material;
a second semiconductor layer of a second bandgap semiconductor material, overlying the first semiconductor layer, the second semiconductor layer being coupled to the first semiconductor layer at an interface, where the second bandgap semiconductor material has a bandgap that is lower than the bandgap of the first bandgap semiconductor material;
the first semiconductor layer having a first drift region of a first conductivity type and a first dopant concentration;
JFET gate regions of a second conductivity type over the first drift region within the first semiconductor layer;
channel regions of the first conductivity type between the JFET gate regions;
a second drift region of the first conductivity type in the second semiconductor layer overlying a top surface of the first semiconductor layer;
a body region of the second conductivity type overlying the second drift layer in the second semiconductor layer;
source regions of the first conductivity type overlying at least portions of the body region in the second semiconductor layer; and
gate trenches formed in the second semiconductor layer extending through the body region and into the second drift region, the gate trenches having an oxide layer and at least partially filled with a conductor to form a MOSFET within the second semiconductor layer.

2. The structure of claim 1 wherein the first semiconductor layer includes a first layer of the first conductivity type abutting the second semiconductor layer, the first layer having a dopant concentration greater than the dopant concentration of the channel regions,
wherein the first layer has a thickness and a dopant concentration configured to achieve tunneling through an interface of the second semiconductor layer and the first layer while the device conducts current.

3. The structure of claim 2 wherein the first layer is continuous across multiple channel regions.

4. The structure of claim 2 wherein the first layer comprises discrete regions between the channel regions.

5. The structure of claim 2 wherein the first layer is even with tops of the channel regions.

6. The structure of claim 2 where the first layer is formed overlying the JFET gate regions and the channel regions.

7. The structure of claim 2 further comprising a second layer of the first conductivity type within the second semiconductor layer and abutting the first layer, the second layer having a dopant concentration higher than that of the second drift region.

8. The structure of claim 2 wherein the first bandgap semiconductor material comprises silicon-carbide (SiC), and the second bandgap semiconductor material comprises silicon (Si), wherein the first semiconductor layer comprises a SiC layer, and the second semiconductor layer comprises a Si layer.

9. The structure of claim 2 wherein the Si layer is wafer-bonded to the SiC layer.

10. The structure of claim 1 wherein the first bandgap semiconductor material comprises silicon-carbide (SiC), and the second bandgap semiconductor material comprises silicon (Si), wherein the first semiconductor layer comprises a SiC layer, and the second semiconductor layer comprises a Si layer.

11. The structure of claim 1 where the conductor in the gate trenches comprises a first conductor portion in a top section of the gate trench and a second conductor portion in a bottom section of the gate trench, the first conductor portion and the second conductor portion being insulated from each other with a dielectric.

12. The structure of claim 1 further comprising a source electrode formed over the second semiconductor layer, the structure further comprising a contact region of the second conductivity type extending between the source electrode and at least one of the JFET gate regions.

13. The structure of claim 12 wherein the contact region is a second conductivity type surrounding a non-gate trench.

14. The structure of claim 13 wherein the contact region surrounds a number of gate trenches.

15. The structure of claim 13 wherein the non-gate trench is at least partially filled with a conductor that contacts the source electrode.

16. The structure of claim 1 further comprising a source electrode formed over the second semiconductor layer, the structure further comprising an insulated conductor extending between the source electrode and at least one of the JFET gate regions.

17. The structure of claim 1 wherein the first bandgap semiconductor material comprises gallium nitride (GaN), and the second bandgap semiconductor material comprises silicon (Si), wherein the first semiconductor layer comprises a GaN layer, and the second semiconductor layer comprises a Si layer.

18. A heterojunction semiconductor device structure, comprising:
a semiconductor silicon carbide (SiC) layer;
a semiconductor silicon (Si) layer overlying the SiC layer, the Si layer being coupled to the SiC layer at an Si/SiC interface;
the SiC layer having a first drift region of a first conductivity type and a first dopant concentration;
JFET gate regions of a second conductivity type over the first drift region within the SiC layer;
channel regions of the first conductivity type between the JFET gate regions;
a second drift region of the first conductivity type in the Si layer overlying a top surface of the SiC layer;
a body region of the second conductivity type overlying the second drift layer in the Si layer;
source regions of the first conductivity type overlying at least portions of the body region in the Si layer; and
planar gates overlying the Si layer configured to invert the body region below the planar gates for forming a conductive channel in the body region when the device is turned on.

19. A method of forming a heterojunction semiconductor device structure comprising:
forming a first semiconductor layer having a first drift region of a first conductivity type and a first dopant concentration, the first semiconductor layer being a first bandgap semiconductor material;
forming JFET gate regions of a second conductivity type over the first drift region within the first semiconductor layer;
forming channel regions of the first conductivity type between the JFET gate regions;
forming an interface layer over the first semiconductor layer;
providing a second semiconductor layer overlying the first semiconductor layer, the second semiconductor layer being a second bandgap semiconductor material having a bandgap narrower than the first bandgap material;
forming a second drift region of the first conductivity type in the second semiconductor layer overlying a top surface of the first semiconductor layer;
forming a body region of the second conductivity type overlying the second drift layer in the second semiconductor layer;
forming source regions of the first conductivity type overlying at least portions of the body region in the second semiconductor layer; and
forming gate trenches in the second semiconductor layer extending through the body region and into the second drift region, the gate trenches having an oxide layer and at least partially filled with a conductor to form a MOSFET within the second semiconductor layer.

20. The method of claim 18 further comprising forming a first layer of the first conductivity type within the first semiconductor layer, the first layer abutting the second semiconductor layer, the first layer having a dopant concentration greater than the dopant concentration of the channel regions,
wherein the first layer has a thickness and a dopant concentration configured to achieve tunneling through an interface of the second semiconductor layer and the first layer while the device conducts current.
